(19) United States
(12) Patent Application Publication
(10) Pub. No.: US 2025/0212665 A1
(43) Pub. Date: Jun. 26, 2025

(54) LIGHT-EMITTING ELEMENT, AND DISPLAY DEVICE INCLUDING THE SAME

(71) Applicant: Samsung Display Co., LTD., Yongin-si (KR)

(72) Inventors: HAKCHOONG LEE, Yongin-si (KR); JONGWON LEE, Yongin-si (KR); CHANG-MIN LEE, Yongin-si (KR); YOONHYEUNG CHO, Yongin-si (KR); JAEHOON HWANG, Yongin-si (KR)

(21) Appl. No.: 18/954,314

(22) Filed: Nov. 20, 2024

(30) Foreign Application Priority Data
Dec. 21, 2023 (KR) 10-2023-0188527

(51) Int. Cl. H10K 59/80

(52) U.S. Cl. CPC H10K 59/8791; H10K 59/873

(57) ABSTRACT

Provided is a light-emitting element including a first electrode, a second electrode facing the first electrode, an emission structure between the first electrode and the second electrode, a first capping layer which is on the second electrode and includes a first compound having a first refractive index of about 1.9 or greater at a wavelength of about 550 nm and a metal dopant having an absorption ratio of about 40% at the wavelength of about 550 nm, and a second capping layer which is on the first capping layer and includes a second compound having second refractive index smaller than the first refractive index, and thus reflectance for external light decrease, thereby exhibiting excellent efficiency characteristics.

### CROSS-REFERENCE TO RELATED APPLICATIONS

The present application claims priority to and the benefit of Korean Patent Application No. 10-2023-0188527, filed on Dec. 21, 2023, the entire disclosure of which is incorporated by reference.

### BACKGROUND

### 1. Field

Embodiments of the present disclosure herein relate to a light-emitting element, and a display device including the same, and, for example, to a light-emitting element including a plurality of capping layers, which are sequentially stacked, and a display device including the same.

### 2. Description of the Related Art

Various suitable types (or kinds) of display devices used for multimedia apparatuses such as a television, a mobile phone, a tablet computer, a navigation system, and a game console are being developed. In such display devices, a so-called self-luminescent display element is used, which achieves a display by causing an emission material containing an organic compound, a quantum dot, and/or the like to emit light.

In applying the light-emitting element to the display device, to improve display quality, it is beneficial to reduce the reflectance caused by external light while maintaining high luminous efficiency of the light-emitting device.

### SUMMARY

Embodiments of the present disclosure provide a light-emitting element in which light reflected and emitted by electrodes is minimized or reduced.

Embodiments of the present disclosure also provide a display device having improved display quality by minimizing or reducing external reflected light.

An embodiment of the present disclosure provides a light-emitting element including: a first electrode; a second electrode facing the first electrode; an emission structure between the first electrode and the second electrode; a first capping layer on the second electrode and including a first compound having a first refractive index of about 1.9 or greater at a wavelength of about 550 nm and a metal dopant having an absorption ratio of about 40% or more at the wavelength of about 550 nm; and a second capping layer on the first capping layer and including a second compound having a second refractive index smaller than the first refractive index.

In an embodiment, a difference between the first refractive index and the second refractive index may be about 0.2 or greater.

In an embodiment, the second refractive index may be about 1.4 to about 1.7.

In an embodiment, the metal dopant may be an alkali metal, an alkaline earth metal, a lanthanide metal, and/or a transition metal.

In an embodiment, the metal dopant may be lithium (Li) and/or ytterbium (Yb).

In an embodiment, a volume ratio of the first compound to the metal dopant in the first capping layer may be about 99:1 to about 95:5

In an embodiment, respective thicknesses of the first capping layer and the second capping layer may be each independently about 100 Å to about 500 Å.

In an embodiment, the emission structure may include an emission layer on the first electrode, a hole transport region between the first electrode and the emission layer, and an electron transport region between the emission layer and the second electrode.

In an embodiment, the emission structure may include: a plurality of emission units, which are sequentially stacked, and each unit includes a hole transport region, an emission layer and an electron transport region, and a charge generation layer, which are between each of the plurality of emission units between the first electrode and the second electrode.

In an embodiment, the emission structure may emit blue light.

In an embodiment, the first compound may be an organic material, and the second compound may be an organic material or inorganic material.

In an embodiment of the present disclosure, a display device includes: a light-emitting element that emits a source light; and an optical control layer on the light-emitting element and that transmits the source light or converts a wavelength of the source light, wherein the light-emitting element includes: a first electrode; a second electrode facing the first electrode; an emission structure between the first electrode and the second electrode; a first capping layer on the second electrode and including a first compound having a first refractive index of about 1.9 or greater at a wavelength of 550 nm, and a metal dopant having an absorption ratio of about 40% or more at the wavelength of 550 nm; and a second capping layer on the first capping layer and including a second compound having a second refractive index smaller than the first refractive index.

In an embodiment, a difference between the first refractive index and the second refractive index may be about 0.2 or greater, and the second refractive index may be about 1.4 to about 1.7.

In an embodiment, the metal dopant may be an alkali metal, an alkaline earth metal, a lanthanide metal, and/or a transition metal.

In an embodiment, a volume ratio of the first compound to the metal dopant in the first capping layer may be about 99:1 to about 95:5.

In an embodiment, respective thicknesses of the first capping layer and the second capping layer may be each independently about 100 Å to about 500 Å.

In an embodiment, the display device may include a first pixel region that emits red light; a second pixel region that emits green light; and a third pixel region that emits blue light, wherein the first pixel region, the second pixel region, and the third pixel region do not overlap each other on a plane, wherein the optical control layer includes: a first optical control member provided corresponding to the first pixel region and including a first quantum dot which converts a wavelength of the source light; a second optical control member provided corresponding to the second pixel region and including a second quantum dot which converts a wavelength of the source light; and a third optical control member provided corresponding to the third pixel region.

In an embodiment of the present disclosure, a display device includes: a circuit layer; a light-emitting element on the circuit layer; and an encapsulation layer on the light-emitting element, wherein the light-emitting element includes: a first electrode; a second electrode facing the first electrode; an emission structure between the first electrode and the second electrode; a first capping layer on the second electrode and including a first compound having a first refractive index of about 1.9 or greater at a wavelength of 550 nm and a metal dopant having an absorption ratio of about 40% or more at the wavelength of 550 nm, and a second capping layer on the first capping layer and including a second compound having a second refractive index smaller than the first refractive index.

In an embodiment, the encapsulation layer may be directly on the second capping layer.

In an embodiment, a volume ratio of the first compound to the metal dopant in the first capping layer may be about 99:1 to about 95:5.

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1A is a perspective view of a display device according to an embodiment;

FIG. 1B is a cross-sectional view of a display device according to an embodiment;

FIG. 1C is a plan view of a display device according to an embodiment;

FIG. 2 is a plan view illustrating an enlarged portion of a display device according to an embodiment;

FIG. 3 is a cross-sectional view of a portion of a display device according to an embodiment;

FIG. 4 is a cross-sectional view of a portion of a display device according to an embodiment;

FIG. 5 is a cross-sectional view of a light-emitting element according to an embodiment;

FIG. 6A is a cross-sectional view of a light-emitting element according to an embodiment;

FIG. 6B is a cross-sectional view illustrating an emission unit included in a light-emitting element according to an embodiment; and

FIG. 7 is a graph comparing optical absorption coefficients of metal dopants according to wavelengths.

### DETAILED DESCRIPTION

In the present disclosure, various suitable modifications may be made, various suitable forms may be applied, and example embodiments will be illustrated in the drawings and described in more detail in the Detailed Description. However, this is not intended to limit the present disclosure to a specific disclosure form, and the present disclosure should be understood to include all changes, equivalents, and substitutes included in the spirit and scope of the present disclosure.

As used herein, when a component (or a region, a layer, a part, etc.) is referred to as being “on”, “connected to”, or “bonded to” other components, it can be directly “disposed/connected to/bonded to” the other component, or a third intervening component may also be present therebetween.

Like reference numerals and symbols refer to like elements. In embodiments, in the drawings, the thickness, the ratio, and the dimensions of elements may be exaggerated for an effective description of technical contents. The term “and/or,” includes all combinations of one or more of which associated configurations may be defined.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

Also, the terms such as “below”, “on the lower side”, “above”, and “on the upper side” may be used to describe the relationships of the components shown in the drawings. The terms are used as a relative concept and are described with reference to the direction indicated in the drawings.

It should be understood that the terms such as “include”, and “have” are intended to specify the presence of stated features, integers, acts, tasks, operations, elements, components, or combinations thereof in the disclosure, but do not preclude the presence or addition of one or more other features, integers, acts, tasks, operations, elements, components, or combinations thereof.

As used herein, when an element is referred to as being “directly on,” another element or layer, there are no intervening layers, films, regions, plates, and the like present between portions such as layers, films, regions, and plates and other portions. For example, an expression that a layer or member that is “directly on” another layer or member may mean that the two layers or two members are provided without using an additional member therebetween.

Unless otherwise defined, all terms (including technical and scientific terms) used herein have the same meaning as commonly understood by one of ordinary skill in the art to which the present disclosure pertains. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a quantum dot according to an embodiment of the present disclosure, a light-emitting element, and a display device including the same will be described with reference to the accompanying drawings.

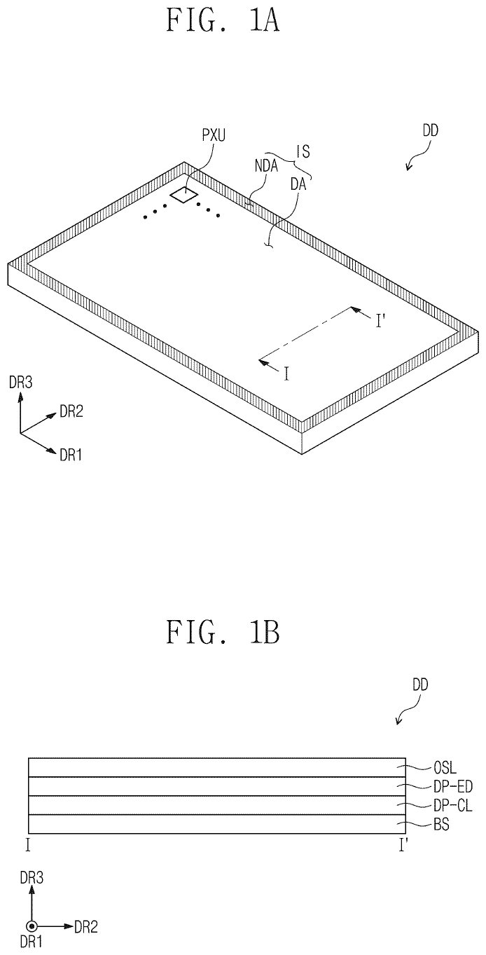

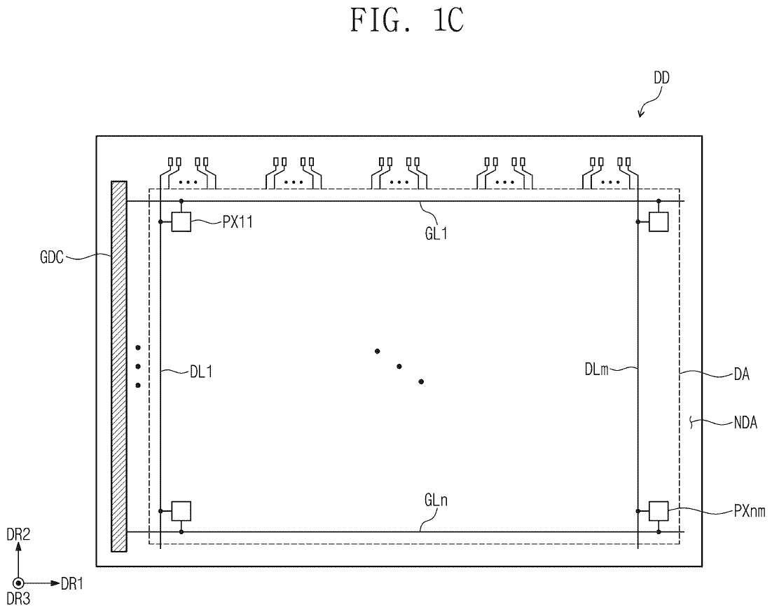

FIG. 1A is a perspective view of a display device according to an embodiment. FIG. 1B is a cross-sectional view of a display device according to an embodiment. FIG. 1C is a plan view of a display device according to an embodiment. FIG. 1B is a cross-sectional view of a section taken along line I-I′ in FIG. 1A.

A display device DD according to an embodiment may be activated in response to an electrical signal and may display an image. For example, the display device DD may be medium- or small-sized devices such as monitors, mobile phones, tablets, navigation units, and/or game consoles, as well as large-sized devices such as televisions, and/or outdoor billboards. However, the display devices according to embodiments are shown as examples but are not limited thereto without departing from the concept of the present disclosure.

The display device DD may be rigid or flexible. The term “flexible” may refer to characteristics capable of being bent. For example, a flexible display device DD may include a curved device, a rollable device, and/or a foldable device.

In FIG. 1A and following drawings, a first direction axis DR1 to a third direction axis DR3 are illustrated. Directions indicated by the first to third direction axes DR1, DR2, and DR3 as described herein are relative concepts, and may be converted into other directions. In embodiments, the directions indicated by the first to third direction axes DR1, DR2, and DR3 may be described as first to third directions DR1, DR2, and DR3, and the same reference symbols and numerals may be used. As used herein, the first direction axis DR1 and the second direction axis DR2 may be perpendicular to each other, and the third direction axis DR3 may be a normal direction to a plane defined by the first direction axis DR1 and the second direction axis DR2.

A thickness direction of the display device DD may be parallel to the third direction axis DR3 which is a normal direction with respect to the plane defined by the first direction axis DR1 and the second direction axis DR2. As used herein, a front surface (or top surface) and a rear surface (or bottom surface) of members that constitute the display device DD may be defined with respect to the third direction axis DR3. The front surface (or top surface) and the rear surface (or bottom surface) of members that constitute the display device DD may be opposite to each other in the third direction DR3, each normal direction of the front surface and the rear surface may be substantially parallel to the third direction DR3. A separation distance between the front surface and the rear surface defined along the third direction DR3 may correspond to a thickness of the member.

As used herein, the term “on the plane” may be defined as a state viewed in the third direction DR3. As used herein, the term “on the cross-section” may be defined as a state viewed in the first direction DR1, or the second direction DR2. In embodiments, the directions indicated by the first to third directions DR1, DR2, and DR3 are relative concepts, and may be changed into another direction.

The display device DD according to an embodiment may display an image through a display surface IS. The display surface IS may include a plane defined by the first direction DR1 and the second direction DR2. The display surface IS may include a display region DA and a non-display region NDA. A plurality of pixel units PXUs may be in the display region DA, and may not be in the non-display region NDA. The non-display region NDA may be defined along an edge of the display surface IS. The non-display region NDA may surround the display region DA. However, an embodiment of the present disclosure is not limited thereto, and, in an embodiment of the present disclosure, the non-display region NDA may be omitted, or provided only on one side of the display region DA.

The pixel units PXUs may define scan lines and columns of pixels. The pixel unit PXU is a minimum repeating unit and may include at least one pixel. The pixel unit PXU may include a plurality of pixels that provide light having different colors.

In an embodiment of the present disclosure, the display device DD, which is provided with a flat display surface IS, is illustrated but is not limited thereto. The display device DD may include a curved display surface or a three-dimensional display surface. The three-dimensional display surface may include a plurality of display regions indicating different directions from each other.

Referring to FIG. 1B, the display device DD may include a base layer BS, a circuit layer DP-CL, and a display layer DP-ED, which are sequentially stacked in a direction of the third direction axis DR3. In embodiments, the display device DD according to an embodiment may further include an optical control member OSL on the display layer DP-ED.

The base layer BS may be a support substrate provided with the circuit layer DP-CL and the display layer DP-ED. The circuit layer DP-CL includes at least one insulating layer (e.g., electrically insulating layer) and circuit element. The circuit element includes signal lines, a driving circuit of a pixel, and/or the like. The circuit layer DP-CL may be formed through forming processes of an insulation layer (e.g., an electrically insulating layer), a semiconductor layer, and a conductive layer (e.g., an electrically conductive layer) via coating and/or deposition, and patterning processes of the insulation layer, the semiconductor layer, and the conductive layer using photolithography. The display layer DP-ED includes a display element. The optical control member OSL may convert a wavelength of light provided by the display element or may transmit light provided from the display element. The optical control member OSL may include a light control pattern and a structure for increasing conversion efficiency of light.

In FIG. 1C, a placement relationship of signal lines GL1 to GLn, DL1 to DLm, and pixels PX11 to PXnm on a plane is illustrated. The signal lines GL1 to GLn, and DL1 to DLm may include a plurality of gate lines GL1 to GLn and a plurality of data lines DL1 to DLm.

The pixels PX11 to PXnm are each connected to a corresponding gate line among the plurality of gate lines GL1 to GLn and a corresponding data line among the plurality of data lines DL1 to DLm. The pixels PX11 to PXnm may each include a pixel driving circuit and a display element. Depending on a configuration of the pixel driving circuit of the pixels PX11 to PXnm, more types (or kinds) of signal lines may be provided in the display device.

Although matrix-type of pixels PX11 to PXnm are illustrated as an example, an arrangement form of the pixels PX11 to PXnm is not limited thereto.

In an embodiment, a gate driving circuit GDC may be integrated into the display device DD through an oxide silicon gate driver circuit (OSG) or amorphous silicon gate driver circuit (ASG) process.

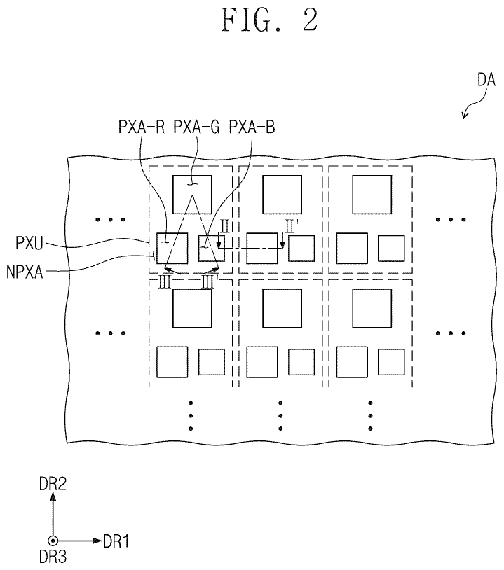

FIG. 2 is an enlarged plan view of a portion of the display device according to an embodiment. Referring to FIG. 2, in an embodiment, a plurality of pixel units PXUs may be in the display region DA. The pixel units PXUs may be each arranged in the first direction DR1 and the second direction DR2. In an embodiment, the pixel unit PXU may include a first pixel, a second pixel, and a third pixel that emit light in different wavelength regions. Red light, green light, and blue light may be output from the first pixel, second pixel, and third pixel, respectively. In FIG. 2, a first pixel region PXA-R, a second pixel region PXA-G, and a third pixel region PXA-B are illustrated, representing the first pixel, the second pixel, and the third pixel, respectively. The first pixel region PXA-R is a region where light generated from the first pixel is provided to the outside, the second pixel region PXA-G is a region where light generated from the second pixel is provided to the outside, and the third pixel region PXA-B may be a region where light generated from the third pixel is provided to the outside. The first to third pixel regions PXA-R, PXA-G, and PXA-B may be separated from each other without overlapping when viewed on a plane.

Referring to FIG. 2, in an embodiment, the three types (or kinds) of pixel regions PXA-R, PXA-G, and PXA-B may be repeatedly arranged throughout the display region DA. The pixel regions PXA-R, PXA-G, and PXA-B may also be referred to as emission regions.

In an embodiment, the first pixel region PXA-R is a red emission region that emits red light, the second pixel region PXA-G is a green emission region that emits green light, and the third pixel region PXA-B may be a blue emission region that emits blue light. However, an embodiment of the present disclosure is not limited thereto, and in an embodiment, a pixel region that emits white light may be further included in the display region DA in addition to the first to third pixel regions PXA-R, PXA-G, and PXA-B.

A peripheral region NPXA is provided around the first to third pixel regions PXA-R, PXA-G, and PXA-B. The peripheral region NPXA may be referred to as the non-emission region. The peripheral region NPXA sets a boundary of the first to third pixel regions PXA-R, PXA-G, and PXA-B.

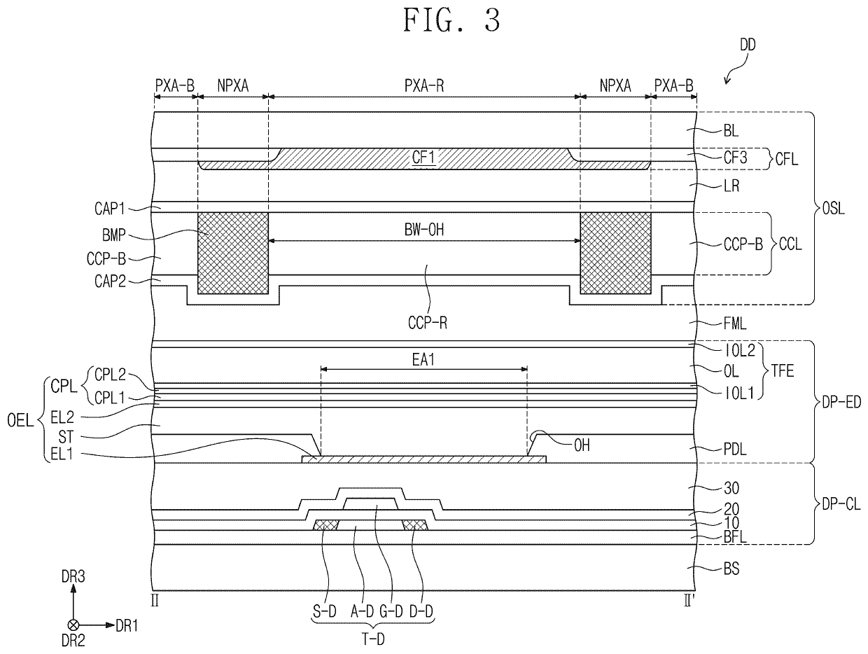

The peripheral region NPXA may be arranged in a form surrounding each of the first pixel region PXA-R, the second pixel region PXA-G, and the third pixel region PXA-B. In embodiments, the peripheral region NPXA may be between the first pixel region PXA-R, the second pixel region PXA-G, and the third pixel region PXA-B. The peripheral region NPXA may set the boundary of the first to third pixel regions PXA-R, PXA-G, and PXA-B, and may prevent or reduce color mixing between the first to third pixel regions PXA-R, PXA-G, PXA-B. In the peripheral region NPXA, a structure preventing or reducing color mixing between the first to third pixel regions PXA-R, PXA-G, and PXA-B, such as a pixel defining layer PDL (FIG. 3) and a division pattern BMP (FIG. 3), may be provided.

In FIG. 2, the display device DD (FIG. 1) which includes the first to third pixel regions PXA-R, PXA-G, and PXA-B having the same planar shape as, and different planar areas from each other, is illustrated as an example but an embodiment of the present disclosure is not limited thereto. The areas of the first to third pixel regions PXA-R, PXA-G, and PXA-B may all be the same, or the area of at least one type (or kind) of pixel region may be different from the areas of the remaining types (or kinds) of pixel regions. The areas of the first to third pixel regions PXA-R, PXA-G, and PXA-B may be set according to the color of the emitted light.

Referring to FIG. 2, the first to third pixel regions PXA-R, PXA-G, and PXA-B may have a rectangular shape on a plane. However, an embodiment of the present disclosure is not limited thereto, and on a plane, the first to third pixel regions PXA-R, PXA-G, and PXA-B may have different polygonal shapes (including substantial polygonal shapes) such as a rhombus, and a pentagon. The first to third pixel regions PXA-R, PXA-G, and PXA-B may have a rectangular shape having rounded corners (e.g., a substantially rectangular shape) on a plane.

In FIG. 2, it is illustrated as an example that the second pixel region PXA-G is provided in a first row, and the first pixel region PXA-R and the third pixel region PXA-B are provided in a second row different from the first row but an embodiment of the present disclosure is not limited thereto and the placement of the first to third pixel regions PXA-R, PXA-G, and PXA-B may be changed in various suitable ways. For example, the first to third pixel regions PXA-R, PXA-G, and PXA-B may be provided in the same row.

The plurality of pixel regions PXA-R, PXA-G, and PXA-B may be arranged in a stripe shape, may have a PENTILE™ arrangement structure (e.g., an RGBG matrix, RGBG structure, or RGBG matrix structure), or may have a DIAMOND PIXEL™ arrangement structure. PENTILE® is a duly registered trademark of Samsung Display Co., Ltd. and DIAMOND PIXEL™ is a trademark of Samsung Display Co., Ltd. However, an embodiment of the present disclosure is not limited thereto, and the arrangement order and arrangement form of a plurality of pixel regions PXA-R, PXA-G, and PXA-B may be provided in various suitable combinations depending on characteristics of display quality, which are required or desired for the display device DD (FIG. 1).

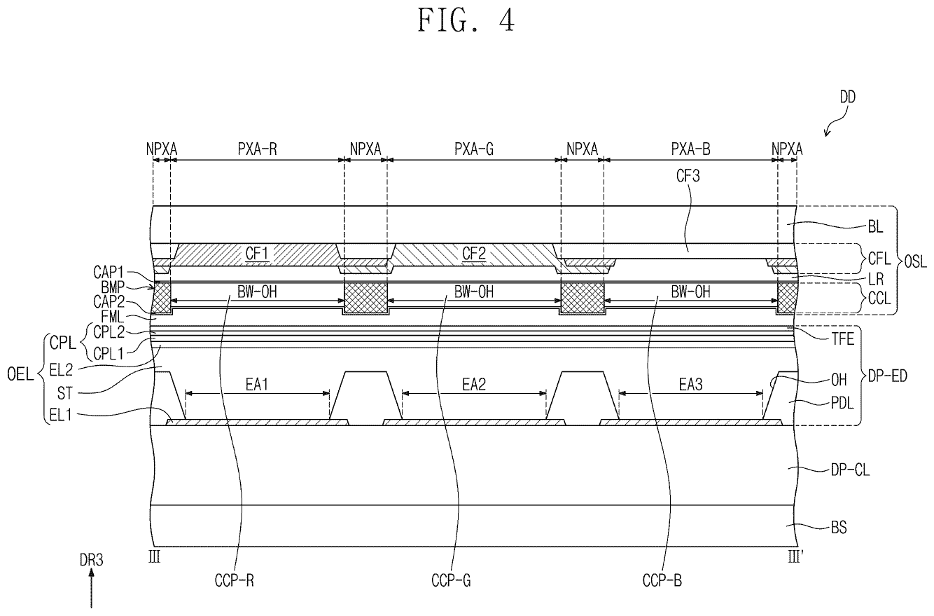

FIG. 3 and FIG. 4 are each a cross-sectional view of a portion of the display device according to an embodiment. FIG. 3 may be a cross-sectional view of a section taken along line II-II′ in FIG. 2, and FIG. 4 may be a cross-sectional view of a section taken along line III-III′ in FIG. 2.

Referring to FIG. 3 and FIG. 4, the display device DD according to an embodiment may include a base layer BS, a circuit layer DP-CL on the base layer BS, and a display layer DP-ED on the circuit layer DP-CL. As used herein, a stacked structure including the base layer BS, the circuit layer DP-CL, and the display layer DP-ED may be referred to as a bottom panel or a display panel. In FIG. 4, unlike FIG. 3, a configuration of the circuit layer DP-CL and an encapsulation layer TFE are briefly illustrated, and a portion in a plurality of pixel regions of the display device is illustrated.

The base layer BS may be a member providing a base surface in which a configuration included in the circuit layer DP-CL is provided. In an embodiment, the base layer BS may be a glass substrate, a metal substrate, a polymer substrate, and/or the like. However, an embodiment of the present disclosure is not limited thereto, and the base layer BS may be an inorganic functional layer or a composite material layer.

The base layer BS may have a multilayered structure. For example, the base layer BS may have a three-layered structure of a polymer resin layer, an adhesive layer, and a polymer resin layer. In embodiments, the polymer resin layer may include a polyimide-based resin. In embodiments, the polymer resin layer may include an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and/or a perylene-based resin. In embodiments, as used herein, the term “α-based” resin refers to a resin including a “α-based” functional group.

The circuit layer DP-CL may be on the base layer BS. The circuit layer DP-CL may include a plurality of transistors. The transistors may each include a control electrode, an input electrode, and an output electrode. For example, the circuit layer DP-CL may include a switching transistor and a driving transistor that drives a light-emitting element OEL of the display layer DP-ED.

In an embodiment, the circuit layer DP-CL may include a transistor T-D as a circuit element. The configuration of the circuit layer DP-CL may suitably vary depending on a design of the driving circuit of the pixels PX11 to PXnm (FIG. 1C). One transistor T-D is illustrated in FIG. 3 as an example, and a placement relationship between an active A-D, a source S-D, and a drain D-D, which constitute the transistor T-D, is provided as an example. The active A-D, source S-D, and drain D-D may be regions distinguished by doping concentration and/or conductivity (e.g., electrical conductivity) in a semiconductor pattern.

The circuit layer DP-CL may include a buffer layer BFL, a first insulation layer 10, a second insulation layer 20, and a third insulation layer 30, etc. For example, the buffer layer BFL, the first insulation layer 10, and the second insulation layer 20 may be inorganic layers, and the third insulation layer 30 may be an organic layer.

The display layer DP-ED may be on the circuit layer DP-CL. The display layer DP-ED may include a pixel defining layer PDL, a light-emitting element OEL, and an encapsulation layer TFE. The light-emitting element OEL may be electrically connected to driving elements of the circuit layer DP-CL, and may display an image by generating light in response to signals provided by the driving elements. The display layer DP-ED may include the light-emitting element OEL as a display element. The light-emitting element OEL may generate a source light.

As illustrated in FIGS. 3-4, the display device DD according to an embodiment may include an optical control member OSL on the display layer DP-ED. The optical control member OSL may include an optical control layer CCL. In an embodiment, the optical control layer CCL may include a quantum dot. The optical control member OSL may include a low-refractive-index layer LR, a color filter layer CFL, and a base substrate BL in addition to the optical control layer CCL. As used herein, the optical control member OSL may be referred to as a top panel.

The optical control layer CCL may be on the display layer DP-ED including the light-emitting element OEL. The optical control layer CCL may include a division pattern BMP and optical control elements CCP-R, CCP-G, and CCP-B. The division pattern BMP may be a component that separates a plurality of optical control elements CCP-R, CCP-G, and CCP-B from each other.

The division pattern BMP may include a base resin and an additive. The base resin may be formed of various suitable resin compositions which are generally referred to as a binder. The additive may include a coupling agent and/or a photoinitiator. The additive may further include a dispersant.

The division pattern BMP may include a black coloring agent for light blocking. The division pattern BMP may include a black dye and/or black pigment, which is mixed into the base resin. In an embodiment, a black ingredient may include carbon black and/or may include a metal such as chromium and/or oxides thereof.

An opening BW-OH may be defined corresponding to a light-emitting opening OH in the division pattern BMP. On a plane, the opening BW-OH overlaps the light-emitting opening OH and has a larger area than the light-emitting opening OH. In embodiments, the opening BW-OH may have a larger area than the emission regions EA1, EA2, and EA3 defined by the light-emitting opening OH. The optical control elements CCP-R, CCP-G, CCP-B may be inside the opening BW-OH.

In an embodiment, the optical control layer CCL may include the first optical control element CCP-R corresponding to the first pixel region PXA-R, the second optical control element CCP-G corresponding to the second pixel region PXA-G, and the third optical control element CCP-B corresponding to the third pixel region PXA-B. The first optical control element CCP-R may be a red optical control element that emits red light, and the second optical control element CCP-G may be a green optical control element that emits green light. The third optical control element CCP-B may be a blue optical control element that emits blue light. In embodiments, the third optical control element CCP-B may be a transmission optical control element that emits the source light provided from the display layer DP-ED by transmitting the source light.

At least some of the plurality of optical control elements CCP-R, CCP-G, and CCP-B may change optical properties of the source light. In an embodiment, at least some of the optical control elements CCP-R, CCP-G, and CCP-B may include a quantum dot that changes the optical properties of source light.

In an embodiment, the first optical control element CCP-R may include a quantum dot that changes the optical properties of source light. The quantum dot included in the first optical control element CCP-R may convert the source light into light having a different wavelength. For example, in the first optical control element CCP-R overlapping the first pixel region PXA-R, the quantum dot may convert the source light into red light.

In this specification, the term quantum dot refers to a crystal of a semiconductor compound. The quantum dot may emit light having various suitable emission wavelengths depending on a size of the crystal. The quantum dot may emit light having various suitable emission wavelengths by adjusting an element ratio in the quantum dot compound.

The quantum dot may have a diameter, for example, about 1 nm to about 10 nm. The quantum dot may be synthesized by a wet chemical process, an organometallic chemical vapor deposition process, a molecular beam epitaxy process, and/or similar processes thereto.

Among the quantum dot manufacturing processes, the wet chemical process is a method of growing a quantum dot particle crystal after mixing an organic solvent and a precursor material. When the quantum dot particle crystal grows, the organic solvent may naturally act as a dispersant coordinated to a surface of the quantum dot crystal and may control the growth of the particle crystal. Therefore, the wet chemical process is easier than vapor deposition methods such as metal organic chemical vapor deposition (MOCVD) or molecular beam epitaxy (MBE) and may control the growth of quantum dot particles through a low-cost process.

A core of the quantum dot may be selected from among a Group II-VI compound, a Group III-V compound, a Group III-VI compound, a Group 1-Ill-VI compound, a Group IV-VI compound, a Group II—IV-V compound, a Group IV element, a Group IV compound, and any combination thereof.

The Group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. In embodiments, the Group II-VI semiconductor compound may further include a Group I metal and/or a Group IV element. The Group I-II-VI compound may be selected from CuSnS and/or CuZnS, and as the Group II-IV-VI compound, ZnSnS and/or the like may be selected. The Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂ and a mixture thereof.

The Group III-VI compound may include a binary compound such as In₂S₃, In₂Se₃, a ternary compound such as InGaS₃, InGaSe₃, or any combination thereof.

The Group I-III-VI compound may be selected from the group consisting of: a ternary compound selected from the group consisting of AgInS, AgInS₂, CuInS, CuInS₂, AgGaS₂, CuGaS₂, CuGaO₂, AgGaO₂, AgAlO₂ and a mixture thereof; and/or a quaternary compound such as AgInGaS₂, and/or CuInGaS₂.

The Group III-V compound may be selected from the group consisting of: a binary compound selected from the group consisting of GaN, GaP, GaAs, GaSb, AlN, AlP, AlAs, AlSb, InN, InP, InAs, InSb and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb and a mixture thereof; and a quaternary compound consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof. In embodiments, the Group III-V compound may further include a Group II metal. For example, InZnP and/or the like may be selected as a Group III-II-V compound.

The Group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe and a mixture thereof; and a quaternary compound selected from the group consisting of SnPbSSe, SnPbSeTe, SnPbSTe, and a mixture thereof.

An example of the Group II-IV-V semiconductor compound may be a ternary compound selected from the group consisting of ZnSnP, ZnSnP₂, ZnSnAs₂, ZnGeP₂, ZnGeAs₂, CdSnP₂, CdGeP₂ and a mixture thereof.

The Group IV element may be selected from the group consisting of Si, Ge, and a mixture thereof. The Group IV compound may be a binary compound selected from the group consisting of SiC, SiGe, and a mixture thereof.

Each element contained in the multi-component compounds such as the binary compound, the ternary compound, and the quaternary compound may be present in particles at a uniform concentration or a non-uniform concentration. In embodiments, formula notation representing quantum dots may mean types (or kinds) of the elements included in the compound, and an element ratio in the compound may differ. For example, AgInGaS₂ may mean AgInₓGa₁₋ₓS₂ (where x is a real number between 0 to 1).

In this case, the binary compound, the ternary compound, and/or the quaternary compound may be present in a particle at a uniform concentration or may be present in the same particle while being divided into states in which concentration distributions are partially different. In embodiments, the binary compound, the ternary compound, and/or the quaternary compound may also have a core-shell structure in which one quantum dot surrounds another quantum dot. The core-shell structure may have a concentration gradient in which the concentrations of the elements present in the shell may gradually decrease along a direction toward the core.

In some embodiments, the quantum dots QD1, QD2, and QD3 may have a core-shell structure including a core containing the above-described nanoparticle, and a shell surrounding the core. The shell of the quantum dots QD1, QD2, and QD3 may serve as a protective layer for preventing or reducing chemical alteration to the core to maintain semiconductor characteristics and/or a charging layer for imparting electrophoretic properties to the quantum dots. The shell may be a single layer or a multilayer. Examples of the shell of the quantum dots QD1, QD2, and QD3 may include an oxide of metal and/or non-metal, a semiconductor compound, or a combination thereof.

For example, examples of the oxide of metal or non-metal may include: binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; and/or ternary compounds such as MgAl₂O₄, CoFe₂O₄, NiFe₂O₄, and/or CoMn₂O₄, but an embodiment of the present disclosure is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like. However, an embodiment of the present disclosure is not limited thereto.

The quantum dot may have a full width of half maximum (FWHM) of an emission wavelength spectrum of about 45 nm or less, for example, about 40 nm or less, or, about 30 nm or less. When the FWHM falls within these ranges, color purity and/or color reproducibility may be improved. In embodiments, light emitted through the quantum dot may be emitted in all (e.g., substantially all) directions, and thus an optical viewing angle may be improved.

In embodiments, the form of the quantum dot is not particularly limited as long as it is a form generally used in the art, but, for example, the quantum dots in the form of spherical, pyramidal, multi-arm, and/or cubic nanoparticles, nanotubes, nanowires, nanofibers, nanoplatelets, and/or the like may be used.

An energy band gap of the quantum dot may be adjusted by adjusting a size of the quantum dot and/or adjusting an element ratio in the quantum dot compound, and thus light having various suitable wavelengths may be emitted in the quantum dot emission layer. Therefore, when the quantum dots as previously described (e.g., quantum dots having different sizes and/or having different element ratios in the quantum dot compound) are used, a light-emitting element emitting light having various suitable wavelengths may be achieved. In embodiments, adjustments in sizes of the quantum dots and/or the element ratios in the quantum dot compound may be selected for red, green, and/or blue light to be emitted. In embodiments, the quantum dots may be configured to emit white light by combining light having various colors.

In an embodiment, the quantum dot included in the first optical control element CCP-R which overlaps the first pixel region PXA-R may emit red light. As the particle size of the quantum dot is smaller, the quantum dot may emit light having a short wavelength. For example, in the quantum dot having the same core, the size of the quantum dot that emits green light may be smaller than the particle size of the quantum dot that emits red light. In embodiments, in the quantum dot having the same core, the particle size of the quantum dot that emits blue light may be smaller than the particle size of the quantum dot that emits green light. However, an embodiment of the present disclosure is not limited thereto, and even when the quantum dots have the same core, the particle size thereof may be adjusted according to materials for the formation of the shell, thickness of the shell, and/or the like.

In embodiments, when the quantum dots have various suitable emission colors such as blue, red, and green, the quantum dots having different emission colors may have different materials of the core.

The optical control elements CCP-R, CCP-G, and CCP-B of the optical control layer CCL may include a scatterer (e.g., a light scatterer). The first optical control element CCP-R may include a quantum dot that converts the source light into red light and the scatterer that scatters light.

The scatterer may be an inorganic particle. For example, the scatterer may include at least one among TiO₂, ZnO, Al₂O₃, SiO₂, and hollow silica. The scatterer may contain any one among TiO₂, ZnO, Al₂O₃, SiO₂, and hollow silica, or may be a mixture of two or more materials selected from among TiO₂, ZnO, Al₂O₃, SiO₂, and hollow silica.

In embodiments, some descriptions of the first optical control element CCP-R described above may be similarly applied to the second optical control element CCP-G and the third optical control element CCP-B.

In an embodiment, the second optical control element CCP-G may include a quantum dot that changes optical properties of the source light. The quantum dot included in the second optical control element CCP-G may convert the source light into light having a different wavelength. For example, in the second optical control element CCP-G overlapping the second pixel region PXA-G, the quantum dot may convert the source light into green light.

In embodiments, the third optical control element CCP-B overlapping the third pixel region PXA-B may include no quantum dot. However, an embodiment of the present disclosure is not limited thereto, and the third optical control element CCP-B may include a quantum dot that converts the wavelength of some of the source light provided from the light-emitting element OEL.

The second optical control element CCP-G and the third optical control element CCP-B may also further include a scatterer (e.g., a light scatterer). For example, in an embodiment, the first optical control element CCP-R may include a first quantum dot and a scatterer (e.g., a light scatterer), the second optical control element CCP-G may include a second quantum dot and a scatterer (e.g., a light scatterer), and the third optical control element CCP-B may include no quantum dot but may include a scatterer (e.g., a light scatterer).

The second optical control element CCP-G and the third optical control element CCP-B may also each include a base resin that disperses the quantum dot and the scatterer.

In the optical control member OSL according to an embodiment illustrated in FIG. 3 and FIG. 4, the base substrate BL may be a member that provides a base surface on which the color filter layer CFL, the low-refractive-index layer LR, the optical control layer CCL, and the like are provided. However, an embodiment of the present disclosure is not limited thereto, and the base substrate BL may be an inorganic layer, an organic layer, or a composite material layer. In embodiments, the base substrate BL may be omitted.

In embodiments, an anti-reflection layer may be on the base substrate BL. The anti-reflection layer may be an optical functional layer that reduces reflectance for external light incident from the outside. The anti-reflection layer may selectively transmit light emitted from the display device DD. In an embodiment, the anti-reflection layer may be a single layer containing a dye and/or a pigment dispersed in the base resin. The anti-reflection layer may be provided as one continuous layer that completely overlaps all of the first to third pixel regions PXA-R, PXA-G, and PXA-B.

The anti-reflection layer may include no polarizer. Therefore, light passing through the anti-reflection layer and incident on the display layer DP-ED may be unpolarized light. The display layer DP-ED may receive unpolarized light from the top of the anti-reflection layer.

In an embodiment, the optical control member OSL may include barrier layers CAP1 and CAP2. The barrier layers CAP1 and CAP2 may serve to prevent or reduce penetration of moisture and/or oxygen (hereinafter, referred to as ‘moisture/oxygen’) and improve optical properties of the optical control member OSL by controlling refractive index. The barrier layers CAP1 and CAP2 may be above and/or under the optical control elements CCP-R, CCP-G, and CCP-B. The barrier layers CAP1, and CAP2 may be only on the top surface or bottom surface of the optical control elements CCP-R, CCP-G, and CCP-B and may block or reduce exposure of the optical control elements CCP-R, CCP-G, and CCP-B to moisture/oxygen, and, for example, may block or reduce exposure of the quantum dots included in the optical control elements CCP-R, CCP-G, and CCP-B to moisture/oxygen. The barrier layers CAP1 and CAP2 may also protect the optical control elements CCP-R, CCP-G, and CCP-B from external shock.

In an embodiment, the first barrier layer CAP1 may be spaced apart from the display layer DP-ED with the optical control elements CCP-R, CCP-G, and CCP-B therebetween. In embodiments, the first barrier layer CAP1 may be on the top surface of the optical control elements CCP-R, CCP-G, and CCP-B. In an embodiment, the optical control member OSL may further include a second barrier layer CAP2 between the optical control elements CCP-R, CCP-G, and CCP-B and the display layer DP-ED. In an embodiment, the first barrier layer CAP1 may cover a top surface, which are adjacent to the low-refractive-index layer LR, of the optical control elements CCP-R, CCP-G, and CCP-B, and the second barrier layer CAP2 may cover a bottom surface, which are adjacent to the display layer DP-ED, of the optical control elements CCP-R, CCP-G, and CCP-B. In embodiments, as used herein, the term “top surface” may be a surface above with respect to the third direction DR3, and the term “bottom surface” may be a surface below with respect to the third direction DR3.

In embodiments, the first barrier layer CAP1 and the second barrier layer CAP2 may cover one surface of the division pattern BMP as well as the optical control elements CCP-R, CCP-G, and CCP-B.

The first barrier layer CAP1 may cover one surface, which is adjacent to the low-refractive-index layer LR, of the division pattern BMP and the optical control elements CCP-R, CCP-G, and CCP-B. The second barrier layer CAP2 may be provided following steps of the division pattern BMP and the optical control elements CCP-R, CCP-G, and CCP-B.

The first barrier layer CAP1 and the second barrier layer CAP2 may be formed by including an inorganic material. In an embodiment, the first barrier layer CAP1 may include silicon oxynitride (SiON). All the first barrier layer CAP1 and the second barrier layer CAP2 may include silicon oxynitride. However, an embodiment of the present disclosure is not limited thereto, and the first barrier layer CAP1 may include silicon oxynitride and the second barrier layer CAP2 may include silicon oxide (SiOₓ).

The optical control member OSL may further include a color filter layer CFL on the optical control layer CCL. The color filter layer CFL includes at least one selected from color filters CF1, CF2, and CF3. The color filter allows light in a set or specific wavelength range to pass through and blocks or reduces transmission of light outside of that wavelength range. In an embodiment, the first color filter CF1 may be a red filter that transmits red light, the second color filter CF2 may be a green filter that transmits green light, and the third color filter CF3 may be a blue filter that transmits blue light.

Each of the color filters CF1, CF2, and CF3 includes a polymer photoresist and a colorant. The colorant may include a pigment and/or a dye. The first color filter CF1 may include a red pigment and/or red dye, the second color filter CF2 may include a green pigment and/or green dye, and the third color filter CF3 may include a blue pigment and/or blue dye. In embodiments, the third color filter CF3 may include no pigment or no dye.

The first to third color filters CF1, CF2, and CF3 may be each provided corresponding to the first pixel region PXA-R, the second pixel region PXA-G, and the third pixel region PXA-B, respectively. In embodiments, the first to the third color filters CF1, CF2, and CF3 may be each provided overlapping, respectively, the first optical control element to the third optical control element CCP-R, CCP-G, and CCP-B.

In embodiments, referring to FIG. 4, a plurality of color filters CF1, CF2, and CF3 that transmit different light may be provided in an overlapping manner corresponding to the peripheral region NPXA. Corresponding to the peripheral region NPXA, the plurality of color filters CF1, CF2, and CF3 may be provided by overlapping in the third direction DR3, which is a thickness direction, to distinguish the boundaries between the adjacent pixel regions PXA-R, PXA-G, and PXA-B. In embodiments, the color filter layer CFL may include a light-blocking part which distinguishes the boundaries between the color filters CF1, CF2, and CF3. The light-blocking part may be formed of the blue filter, or may be formed by including an organic light blocking material and/or inorganic light blocking material that contains a black pigment and/or black dye.

Referring to FIG. 4, in an embodiment, the optical control member OSL may further include a low-refractive-index layer LR. The low-refractive-index layer LR may be between the optical control elements CCP-R, CCP-G, and CCP-B and the color filters CF1, CF2, and CF3, and thus may function as an optical functional layer such as increasing light extraction efficiency of emitted light in the optical control layer CCL, and/or preventing or reducing incidence of reflected light on the optical control layer CCL. The low-refractive-index layer LR may be a layer that has a relatively lower refractive index than adjacent layers.

The low-refractive-index layer LR may include at least one inorganic layer. For example, the low-refractive-index layer LR may be formed by including silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, a metal thin film of which has light transmittance secured. However, an embodiment of the present disclosure is not limited thereto, and the low-refractive-index layer LR may include an organic film. The refractive layer LR may have, for example, a structure in which a plurality of hollow particles are dispersed in an organic polymer resin. The low-refractive-index layer LR may be constituted to include a single layer or a multilayer.

The display device DD according to an embodiment may include a bottom panel that includes a display layer DP-ED and a top panel OSL (optical control member) that includes an optical control layer CCL and a color filter layer CFL, and in an embodiment, a filling layer FML may be between the bottom panel and the top panel. In an embodiment, the filling layer FML may fill between the display layer DP-ED and the optical control member OSL. The filling layer may be directly on the encapsulation layer TFE and the second barrier layer CAP2 may be directly on the filling layer FML. The bottom surface or the filling layer FML may contact the top surface of the encapsulation layer TFE, and the top surface of the filling layer FML may contact the bottom surface of the second barrier layer CAP2.

The filling layer FML may function as a buffer between the display layer DP-ED of the bottom panel and the optical control layer CCL of the top panel. In an embodiment, the filling layer FML may function to absorb a shock, and/or the like and may increase the intensity of the display device DD. The filling layer FML may be formed from a filling resin including a polymer resin. For example, the filling layer FML may be formed of the filling resin which includes an acryl-based resin, an epoxy-based resin, and/or the like.

In embodiments, a structure of each member in the display device DD illustrated in FIG. 3 and FIG. 4 is an example, but an embodiment of the present disclosure is not limited thereto. For example, in the optical control member OSL, the base substrate BL may be omitted and/or the filling layer FML may be omitted. A configuration of the optical control layer CCL and/or the color filter layer CFL may be different, and/or the optical control member OSL may further include additional optical functional layers in addition to the illustrated configuration.

Referring to FIG. 3 and FIG. 4, a light-emitting opening OH is defined in the pixel defining layer PDL of the display layer DP-ED. The light-emitting opening OH of the pixel defining layer PDL may expose at least a portion of the first electrode EL1. In an embodiment, emission regions EA1, EA2, and EA3 may be defined by the light-emitting opening OH.

The pixel defining layer PDL may be formed of a polymer resin. For example, the pixel defining layer PDL may be formed by including a polyacryl-based resin and/or a polyimide-based resin. In embodiments, the pixel defining layer PDL may be formed by further including an inorganic material in addition to the polymer resin. In embodiments, the pixel defining layer PDL may be formed by including a light-absorbing material and/or including a black pigment and/or black dye. The pixel defining layer PDL formed by including the black pigment and/or black dye may implement a black pixel defining layer. When forming the pixel defining layer PDL, carbon black and/or the like may be used as the black pigment and/or the black dye, but an embodiment of the present disclosure is not limited thereto.

In embodiments, the pixel defining layer PDL may be formed of an inorganic material. For example, the pixel defining layer PDL may be formed of an inorganic material such as silicon nitride (SiNx), silicon oxide (SiOx), and/or silicon oxynitride (SiOxNy).

Referring to FIG. 3 and FIG. 4, the display device DD may include a first emission region EA1, a second emission region EA2, and a third emission region EA3. The first emission region EA1, the second emission region EA2, and the third emission region EA3 may be regions which are separated by the pixel defining layer PDL. The first emission region EA1, the second emission region EA2, and the third emission region EA3 may correspond to the first pixel region PXA-R, the second pixel region PXA-G, and the third pixel region PXA-B, respectively. In embodiments, as used herein, the term “correspond” means that two components overlap when viewed in the thickness direction DR3 of the display device DD and is not limited to the two components having the same area.

The emission regions EA1, EA2, and EA3 may overlap the pixel regions PXA-R, PXA-G, and PXA-B. When viewed on a plane, areas of the pixel regions PXA-R, PXA-G, and PXA-B, which are separated by the division pattern BMP, may be larger than areas of the emission regions EA1, EA2, and EA3, which are separated by the pixel defining layer PDL.

In the display device DD according to an embodiment, the light-emitting element OEL may generate a source light. In an embodiment, the source light may be white light or blue light. In an embodiment, the display layer DP-ED may include a light-emitting diode as the light-emitting element OEL. An emission structure ST included in the light-emitting element OEL may include an organic emission material and/or inorganic emission material as an emission material.

The light-emitting element OEL includes a first electrode EL1, a second electrode EL2 facing the first electrode EL1, and an emission structure ST between the first electrode EL1 and the second electrode EL2. In embodiments, the light-emitting element OEL includes a capping layer CPL on the second electrode EL2. The capping layer CPL includes a first capping layer CPL1 and a second capping layer CPL2, which are stacked in a thickness direction to be distinguished.

The display layer DP-ED may include an encapsulation layer TFE that protects the light-emitting element OEL. The encapsulation layer TFE may include an organic material and/or inorganic material. The encapsulation layer TFE may have a multi-layered structure in which an inorganic layer/organic layer is repeated. In an embodiment, the encapsulation layer TFE may include a first inorganic layer IOL1, an organic layer OL, and a second inorganic layer IOL2, which are sequentially stacked. However, the layers constituting the encapsulation layer TFE are not limited thereto. The encapsulation layer TFE may be directly provided on the light-emitting element OEL in continuous processes.

In an embodiment, the encapsulation layer TFE may be directly on the capping layer CPL. The encapsulation layer TFE may be directly on the second capping layer CPL2.

The first and second inorganic layers IOL1 and IOL2 may protect the light-emitting element OEL from moisture and oxygen, and the organic layer may protect the light-emitting element OEL from foreign materials such as dust particles. For example, the organic layer OL may prevent or reduce defects due to scratches in the light-emitting element OEL caused by foreign materials introduced during the manufacturing process. In embodiments, the display device DD may be above the encapsulation layer TFE, and may further include a refractive index control layer that improves light extraction efficiency.

The inorganic layers IOL1, and IOL2 may include at least one among silicon nitride, silicon oxynitride, silicon oxide, titanium oxide, and aluminum oxide. The organic layer OL may include an acryl-based organic material. However, types (or kinds) of materials constituting the inorganic layers IOL1, and IOL2 and the organic layer OL are not limited thereto.

In the display device DD according to an embodiment, the display layer DP-ED may be a self-luminous type (or kind) of display layer. For example, the display layer DP-ED may include a micro LED display layer, a nano LED display layer, an organic emission display layer, and/or a quantum dot emission display layer. However, this is for illustrative purposes, and the display layer is not limited thereto as long as the display elements achieve the self-luminous type (or kind) of display layer.

The organic emission display layer may include an organic electroluminescence element including an organic emission material. The quantum dot emission display layer may include an emission layer including a quantum dot and/or a quantum rod. The micro LED display layer may include a micro light-emitting diode element, which is an ultra small light-emitting element, and the nano LED display layer may include a nano light-emitting diode element. Hereinafter, the display layer DP-ED is described as an organic emission display layer. However, a configuration other than the emission layer may be similarly applied to structures of other display layers than the organic emission display layer.

The first electrode EL1 of the light-emitting element OEL according to an embodiment is on the circuit layer DP-CL. The first electrode EL1 may be directly or indirectly connected to a transistor T-D, and the connection structure between the first electrode EL1 and the transistor T-D is not illustrated in FIG. 3. The first electrode EL1 may be an anode or a cathode. In embodiments, the first electrode EL1 may be a pixel electrode. The first electrode EL1 may be a transmissive electrode, a transflective electrode, or a reflective electrode.

The second electrode EL2 may be on the first electrode EL1. The second electrode EL2 may be a cathode, or an anode. In an embodiment, if the first electrode EL1 is a cathode, the second electrode EL2 may be an anode, and if the first electrode EL1 is an anode, the second electrode EL2 may be a cathode. The second electrode EL2 may be a common electrode. However, an embodiment of the present disclosure is not limited thereto. The second electrode EL2 may be a transmissive-type electrode, a transflective-type electrode, or a reflective-type electrode.

The emission structure ST may include at least one emission unit. In an embodiment, the emission structure ST of the light-emitting element OEL may include one emission unit, or may be provided in a stacked form of a plurality of emission units. If the emission structure ST is in the stacked form of a plurality of emission units, the emission structure ST may be distinguished from each other, and may include two or more emission units stacked in a third direction DR3, which is a thickness direction. In embodiments, each unit emission unit may include a plurality of functional layers. In embodiments, each unit emission unit may include at least one emission layer as a functional layer.

In an embodiment, the emission structure ST may be provided overlapping the pixel regions PXA-R, PXA-G, and PXA-B. In an embodiment, the emission structure ST may be commonly provided in the pixel regions PXA-R, PXA-G, and PXA-B. The emission structure ST may be a structure in which a plurality of functional layers are stacked, and in an embodiment, all the plurality of functional layers included in the emission structure ST may be commonly provided in entire pixel regions PXA-R, PXA-G, and PXA-B.

However, an embodiment of the present disclosure is not limited thereto. At least one functional layer constituting the emission structure ST may be formed separately for each of the first to third pixel regions PXA-R, PXA-G, and PXA-B. In an embodiment, at least one functional layer may be patterned in the light-emitting opening OH, and formed separately for each of the first to third pixel regions PXA-R, PXA-G, and PXA-B.

The light-emitting element OEL according to an embodiment includes a capping layer CPL on the second electrode EL2. The capping layer CPL may include a plurality of layers that are sequentially on the second electrode EL2. The light-emitting element OEL according to an embodiment may include a first capping layer CPL1 on the second electrode EL2, and a second capping layer CPL2 on the first capping layer CPL1. The second capping layer CPL2 may be directly on the first capping layer CPL1. The first capping layer CPL1 may be directly on the second electrode EL2.

The first capping layer CPL1 and the second capping layer CPL2 may have different refractive indices. A first compound included in the first capping layer CPL1 and a second compound included in the second capping layer CPL2 may have different refractive indices. The first capping layer CPL1 may include the first compound having a high refractive index property and the second capping layer CPL2 may include the second compound having a relatively lower refractive index property compared to the first capping layer CPL1. In embodiments, the first capping layer CPL1 may include a metal dopant in addition to the high refractive index material.

In the capping layer CPL according to an embodiment, the metal dopant of the first capping layer CPL1 may absorb some of light reflected from the first electrode EL1 or second electrode EL2. In embodiments, a stacked structure of the first capping layer CPL1 having the high refractive index property and the second capping layer CPL2 having the low refractive index property may be included, and thus destructive interference of light reflected from the first electrode EL1 or the second electrode EL2 may be achieved by the capping layer CPL. Therefore, in the light-emitting element OEL according to an embodiment including the capping layer CPL according to an embodiment, reflectance for external light may be reduced. In embodiments, in the display device DD according to an embodiment including the capping layer CPL according to an embodiment, the reflectance for the external light may be reduced, and thereby the display device DD is capable of showing an excellent display quality.

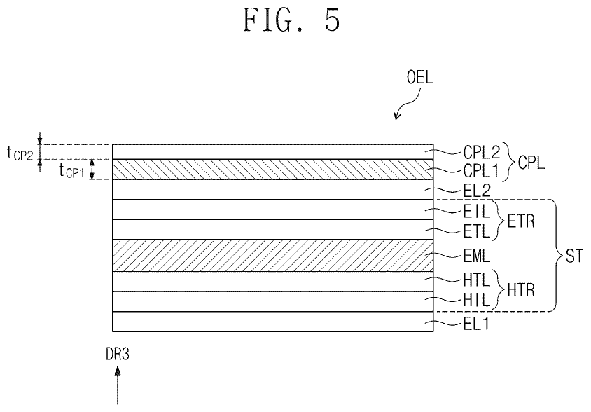

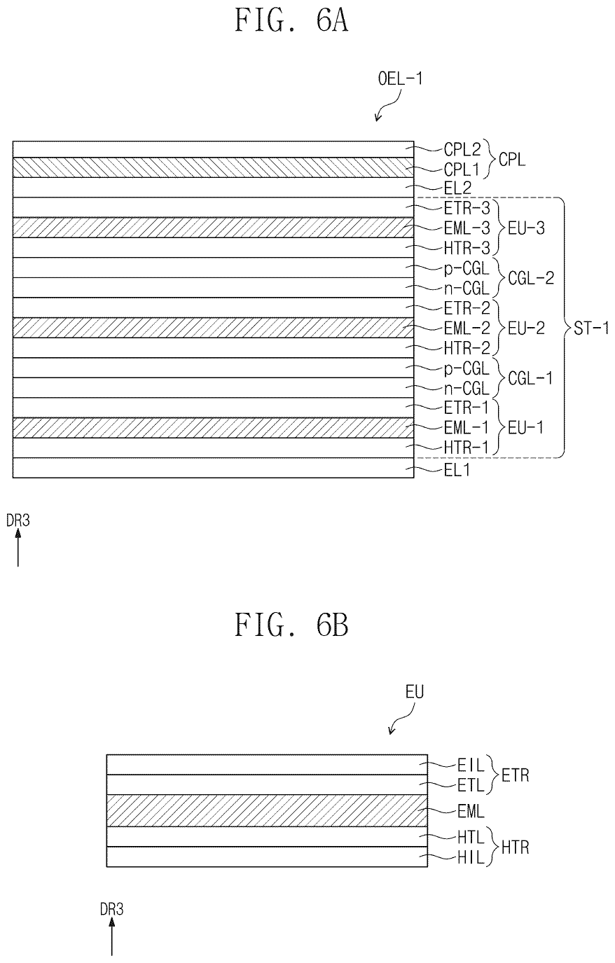

The light-emitting element included in the display device DD according to an embodiment will be described with reference to FIG. 5 to FIG. 6B below. FIG. 5 and FIG. 6A are each a cross-sectional view of the light-emitting element according to an embodiment. FIG. 6B is a cross-sectional view of an emission unit according to an embodiment included in FIG. 6A.

The light-emitting element OEL according to an embodiment illustrated in FIG. 5 corresponds to an embodiment where one emission unit is included, and a light-emitting element OEL-1 according to an embodiment illustrated in FIG. 6A corresponds to an embodiment where a plurality of emission units EU-1, EU-2, and EU-3 is included, which are stacked.

In an embodiment illustrated in FIG. 5 and FIG. 6A, the first electrode EL1 of the light-emitting elements OEL and OEL-1 may be formed of a metal material, a metal alloy, and/or a conductive compound (e.g., an electrically conductive compound). The first electrode EL1 may be an anode or a cathode. However, an embodiment of the present disclosure is not limited thereto. In embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, and an oxide thereof.

If the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, and/or a compound and/or mixture thereof (for example, a mixture of Ag and Mg). In embodiments, the first electrode EL1 may have a multi-layered structure including a reflective film or transflective film formed of the material described above, and a transparent conductive film formed of indium tin oxide (ITO), indium zinc oxide (IZO), zinc oxide (ZnO), indium tin zinc oxide (ITZO), and/or the like. For example, the first electrode EL1 may have a three-layered structure of ITO/Ag/ITO but is not limited thereto. In embodiments, an embodiment of the present disclosure is not limited thereto, and the first electrode EL1 may include the above-described metal material, a combination of two or more metal materials selected from among the above-described metal materials, an oxide of the above-described metal materials, and/or the like. The first electrode EL1 may have a thickness of about 700 Å to about 10000 Å. For example, the first electrode EL1 may have a thickness of about 1000 Å to about 3000 Å.

The emission structure ST may include a hole transport region HTR, an emission layer EML, and an electron transport region ETR, as a functional layer. In FIG. 5, the emission layer EML is illustrated as one layer, but is illustrated for illustrative purposes, and the emission layer EML may have a structure in which a single layer or a plurality of layers are stacked.

The hole transport region HTR may be between the first electrode EL1 and the emission layer EML. In FIG. 5, the hole transport region HTR is illustrated to include a hole injection layer HIL and a hole transport layer HTL, but an embodiment of the present disclosure is not limited thereto, at least one among the hole injection layer HIL and the hole transport layer HTL may be omitted, and/or an emission auxiliary layer and an electron blocking layer may further be included in addition to the hole injection layer HIL and the hole transport layer HTL.

The hole transport region HTR may have a single layer formed of a single material, a single layer formed of a plurality of different materials, or a multi-layered structure having a plurality of layers formed of a plurality of different materials.

For example, the hole transport region HTR may have a single-layered structure of the hole injection layer HIL or the hole transport layer HTL, and may have a single-layered structure formed of a hole injection material and a hole transport material. In embodiments, the hole transport region HTR may have a structure of a single layer formed of a plurality of different materials, or may have a structure of a hole injection layer HIL/hole transport layer HTL, a hole injection layer HIL/emission auxiliary layer, a hole transport layer HTL/emission auxiliary layer, a hole transport layer HTL/electron blocking layer, a hole injection layer HIL/hole transport region HTL/emission auxiliary layer, or a hole injection layer HIL/hole transport layer HTL/electron blocking layer, which are sequentially stacked from the first electrode EL1. However, an embodiment of the present disclosure is not limited thereto. In embodiments, the hole transport layer HTL may have a single layer, or may have a multi-layered structure having a plurality of layers.

The hole transport region HTR may include a carbazole-based derivative such as N-phenylcarbazole and/or polyvinylcarbazole, a fluorene-based derivative, a triphenylamine-based derivative such as N,N′-bis(3-methylphenyl)-N,N′-diphenyl-[1,1′-biphenyl]-4,4′-diamine (TPD), and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), and/or 1,3-bis(1,8-dimethyl-9H-carbazol-9-yl)benzene (mDCP), and/or the like.

The hole transport region HTR, in addition to the above-described materials, may further include a charge generation material for improving conductivity (e.g., electrical conductivity). The charge generation material may be, for example, a p-dopant. The p-dopant may include at least one among a halogenated metal compound, a quinone derivative, a metal oxide, and a cyano-containing compound, but is not limited thereto. For example, the p-dopant may include: a halogenated metal compound such as CuI, and/or RbI; a quinone derivative such as tetracyanoquinodimethane (TCNQ), and/or 2,3,5,6-tetrafluoro-7,7′8,8-tetracyanoquinodimethane (F4-TCNQ); a metal oxide such as tungsten oxide and/or molybdenum oxide; and/or a cyano-containing compound such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), but an embodiment of the present disclosure is not limited thereto.

For example, in an embodiment, the hole transport region HTR may include at least one among Compounds NPB, and TCTA below.

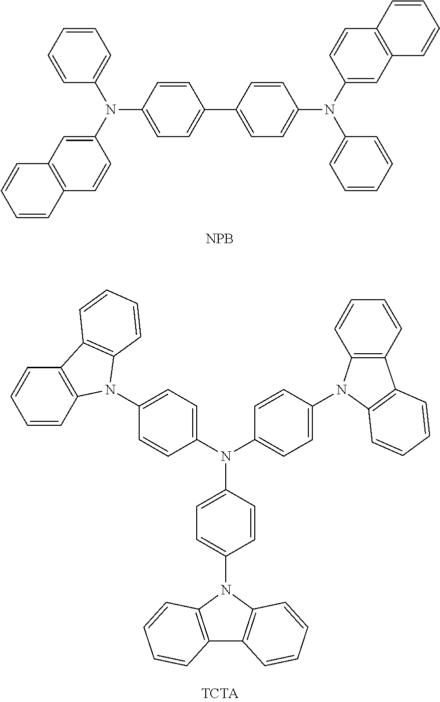 [SMILES: c1ccc(N(c2ccc(-c3ccc(N(c4ccccc4)c4ccc5ccccc5c4)cc3)cc2)c2ccc3ccccc3c2)cc1 ; "NPB" ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

In the light-emitting element OEL according to an embodiment, the emission layer EML may be provided on the hole transport region HTR. The emission layer EML may have a thickness of, for example, about 100 Å to about 1000 Å, or about 100 Å to about 300 Å. The emission layer EML may include an emission material. The emission layer EML may have a single layer formed of a single material, a single layer formed of a plurality of different materials, or a multi-layered structure having a plurality of layers formed of a plurality of different materials. The emission layer EML may contain fluorescent and/or phosphorescent materials. In the light-emitting element OEL according to an embodiment, the emission layer EML may include an organic emission material, an organic metal complex, quantum dots, and/or the like as the emission materials.

In the light-emitting element OEL according to an embodiment, the emission layer EML may include an anthracene derivative, a pyrene derivative, a fluoranthene derivative, a chrysene derivative, a dihydrobenzanthracene derivative, and/or a triphenylene derivative. In embodiments, the emission layer EML may include an anthracene derivative, and/or a pyrene derivative.

The emission layer EML may include a host and a dopant. For example, the emission layer EML may include at least one among bis(4-(9H-carbazol-9-yl)phenyl) diphenylsilane (BCPDS), (4-(1-(4-(diphenylamino)phenyl) cyclohexyl)phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(N-carbazolyl)benzene (mCP), 2,8-bis(diphenylphosphoryl)dibenzo[b,d]furan (PPF), 4,4′,4″-tris(N-carbazolyl)-triphenylamine (TCTA) and 1,3,5-tris(1-phenyl-1H-benzo[d]imidazole-2-yl)benzene (TPBi). However, an embodiment of the present disclosure is not limited thereto, and, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like. may be used as a host material.

In an embodiment, the emission layer EML may include, as a dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl(DPAVBi), perylene and/or a derivative thereof (e.g., 2,5,8,11-tetra-t-butylperylene (TBP)), pyrene and/or a derivative thereof (e.g., 1,1-dipyrene, 1,4-dipyrenylbenzene, 1,4-bis(N, N-diphenylamino)pyrene), and/or the like.

The emission layer EML may further include any suitable phosphorescent dopant material generally used in the art. In embodiments, as the phosphorescent dopant, a metal complex containing iridium (Ir), platinum (Pt), osmium (Os), gold (Au), titanium (Ti), zirconium (Zr), hafnium (Hf), europium (Eu), terbium (Tb), and/or thulium (Tm) may be utilized. In embodiments, iridium(III) bis(4,6-difluorophenylpyridinato-N,C2′)picolinato (Flrpic), bis(2,4-difluorophenylpyridinato)-tetrakis(1-pyrazolyl)borate iridium(III) (FIr6), and/or platinum octaethyl porphyrin (PtOEP) may be used as the phosphorescent dopant. However, an embodiment of the present disclosure is not limited thereto.

For example, the emission layer according to an embodiment may include Compound H1 below as a host, and Compound D1 below as a dopant. However, an embodiment of the present disclosure is not limited thereto.

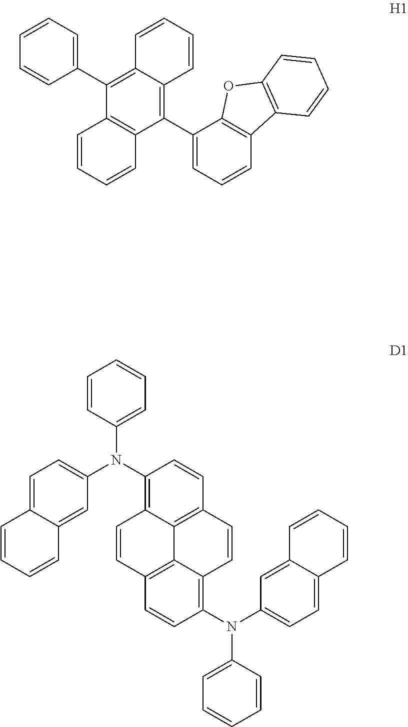 [SMILES: c1ccc(-c2c3ccccc3c(-c3cccc4c3oc3ccccc34)c3ccccc23)cc1 ; c1ccc(N(c2ccc3ccccc3c2)c2ccc3ccc4c(N(c5ccccc5)c5ccc6ccccc6c5)ccc5ccc2c3c54)cc1]

In embodiments, the emission layer EML may include a quantum dot material. The descriptions for quantum dot materials in the above-described optical control layer CCL (FIG. 4) may be similarly applied to the quantum dot material.

In the light-emitting element OEL according to an embodiment, the electron transport region ETR may be provided on the emission layer EML. The electron transport region ETR may include at least one among an electron transport layer ETL and an electron injection layer EIL, but an embodiment of the present disclosure is not limited thereto. The electron transport region ETR may further include a hole-blocking layer in addition to the electron transport layer ETL and the electron injection layer EIL. The electron transport region ETR may have a single layer formed of a single material, a single layer formed of a plurality of different materials, or a multi-layered structure having a plurality of layers formed of a plurality of different materials.

For example, the electron transport region ETR may have a single-layered structure of an electron injection layer EIL or an electron transport layer ETL, and may also have a single-layered structure formed of an electron injection material and an electron transport material. In embodiments, the electron transport region ETR may have a single-layered structure formed of a plurality of different materials, or may have structures of an electron transport layer ETL/electron injection layer EIL, or a hole blocking layer/electron transport layer ETL/electron injection layer EIL, in which each layer is sequentially stacked, but is not limited thereto. The electron transport region ETR may have a thickness of, for example, about 1000 Å to about 1500 Å.

The electron transport region ETR may include an anthracene-based compound. However, an embodiment of the present disclosure is not limited thereto, and the electron transport region ETR may include, for example: tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/or 2,4,6-tris(biphenyl-3-yl)-1,3,5-triazine (T2T); and/or 2,4,6-tris(3-(pyrimidin-5-yl)phenyl)-1,3,5-triazine (TPM-TAZ); and/or a mixture thereof.

In embodiments, the electron transport region ETR may include: a metal halide such as LiF, NaCl, CsF, RbCl, RbI, CuI, and/or KI; a lanthanide metal such as Yb; and/or a co-deposition material of the above-described halide metal and lanthanide metal. For example, the electron transport region ETR may include KI:Yb, RbI:Yb, LiF:Yb, and/or the like as the co-deposition material. In embodiments, a metal oxide such as Li₂O, and/or BaO, 8-hydroxyl-Lithium quinolate (Liq), and/or the like may be used in the electron transport region ETR, but an embodiment of the present disclosure is not limited thereto. The electron transport region ETR may be also formed of a mixed material of the electron transport material and an insulating organo metal salt (e.g., an electrically insulating organo metal salt). The organo metal salt may be a material having an energy band gap of about 4 eV or greater. In embodiments, for example, the organo metal salt may include metal acetate, metal benzoate, metal acetoacetate, metal acetylacetonate, and/or metal stearate.

The electron transport region ETR may further include at least one among 2,9-dimethyl-4,7-diphenyl-1,10-phenanthroline (BCP), diphenyl(4-(triphenylsilyl)phenyl)phosphine oxide (TSPO1) and 4,7-diphenyl-1,10-phenanthroline (Bphen) in addition to the above-described materials, but an embodiment of the present disclosure is not limited thereto.

For example, in an embodiment, the electron transport region ETR may include at least one among compounds below. However, an embodiment of the present disclosure is not limited thereto.

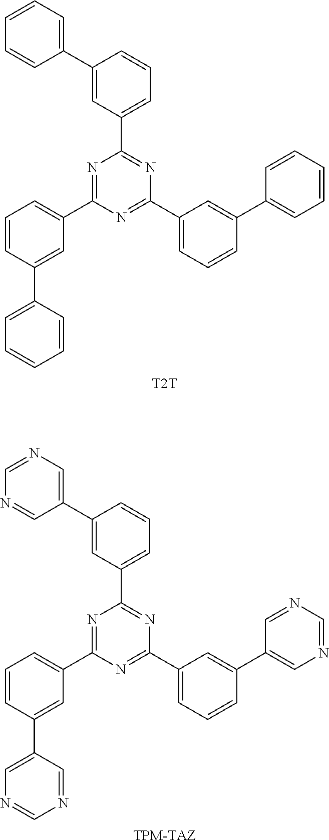 [SMILES: c1ccc(-c2cccc(-c3nc(-c4cccc(-c5ccccc5)c4)nc(-c4cccc(-c5ccccc5)c4)n3)c2)cc1 ; "T2T" ; c1cc(-c2cncnc2)cc(-c2nc(-c3cccc(-c4cncnc4)c3)nc(-c3cccc(-c4cncnc4)c3)n2)c1 ; "TPM-TAZ"]

The second electrode EL2 may be provided on the electron transport region ETR. The second electrode EL2 may be a common electrode. The second electrode EL2 may be a transmissive electrode, a transflective electrode, or a reflective electrode. If the second electrode EL2 is a transmissive electrode, the second electrode EL2 may be formed of a transparent metal oxide such as indium tin oxide (ITO), indium zinc oxide (IZO), zinc oxide (ZnO), indium tin zinc oxide (ITZO), and/or the like.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, and/or a compound or mixture including the same (for example, AgMg, AgYb, or MgYb). In embodiments, the second electrode EL2 may have a multi-layered structure including a reflective film or transflective film formed of the above-described material and a transparent conductive film formed of indium tin oxide (ITO), indium zinc oxide (IZO), zinc oxide (ZnO), indium tin zinc oxide (ITZO), and/or the like. For example, the second electrode EL2 may include the above-described metal material, a combination of two or more metal materials selected from the above-described metal materials, an oxide of the above-described metal materials, and/or the like.

In the light-emitting element OEL according to an embodiment, the emission structure ST may emit blue light. However, an embodiment of the present disclosure is not limited thereto, and the emission structure ST may emit light other than blue light depending on the emission materials included in the emission layer EML of the emission structure ST.

In the display device DD according to an embodiment illustrated in FIG. 4, some of the emission structure ST of the light emitting element OEL may be patterned and provided so as to correspond to the first emission region EA1, the second emission region EA2, and the emission region EA3, respectively. In an embodiment, the emission layer EML among the functional layers constituting the emission structure ST may be separated by a pixel defining layer PDL (FIG. 4) so as to correspond to each of the emission regions EA1, EA2, and EA3 (FIG. 4) of the display layer DP-ED (FIG. 4). In an embodiment, the emission layer EML corresponding to each of the first emission region EA1, the second emission region EA2, and the third emission region EA3 may emit light in a different wavelength region. However, an embodiment of the present disclosure is not limited thereto, even when the emission layer EML is separately provided in the emission regions, the emission layer EML may emit light in the same wavelength region.

The hole transport region HTR and the electron transport region ETR among the emission structure ST may be provided as a common layer in order to overlap the entire first to third pixel regions PXA-R, PXA-G, and PXA-B (FIG. 4). However, an embodiment of the present disclosure is not limited thereto, and at least one among the hole transport region HTR and the electron transport region ETR may be patterned separately in order to include a disconnected portion in the peripheral region NPXA.

The capping layer CPL may be on the second electrode EL2 of the light-emitting element OEL according to embodiment. The capping layer CPL may overlap the entire first to third pixel regions PXA-R, PXA-G, and PXA-B (FIG. 4). The first capping layer CPL1, and the second capping layer CPL2 may be sequentially on the second electrode EL2, and each may be provided on the entire first to third pixel regions PXA-R, PXA-G, and PXA-B (FIG. 4) in a form of a common layer.

In an embodiment, the first capping layer CPL1 may include a first compound having a first refractive index of about 1.9 nm or higher at a wavelength of about 550 nm. In embodiments, the first capping layer CPL1 may include a metal dopant having an absorption ratio of about 40% or more at about 550 nm along with the first compound. The first compound and the metal dopant may be provided by co-deposition to form the first capping layer CPL1.

The first compound may be an organic compound. In the first capping layer CPL1, the first compound may be a main ingredient, and for example, the first compound may be referred to as a host material in the first capping layer CPL1. For example, the light-emitting element OEL according to an embodiment may include Compound CPM1 below in the first capping layer CPL1 as the first compound. However, an embodiment of the present disclosure is not limited thereto, and any suitable organic material having high refractive index characteristics of about 1.9 or higher at a wavelength of about 550 nm may be used as the first compound without limitation.

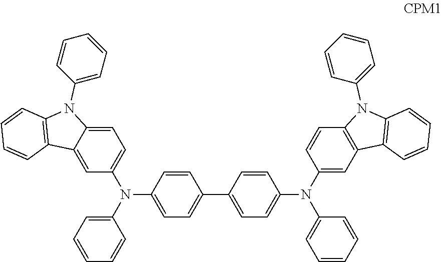 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

The metal dopant contained in the first capping layer CPL1 may be selected from among an alkali metal, an alkaline earth metal, a lanthanide metal, and/or a transition metal. The metal dopant contained in the first capping layer CPL1 may be an alkali metal, an alkaline earth metal, a lanthanide metal, and/or a transition metal, and may have an absorption ratio of about 40% or more at a wavelength of about 550 nm. For example, the metal dopant contained in the capping layer CPL1 may be lithium (Li), and/or ytterbium (Yb). However, an embodiment of the present disclosure is not limited thereto, and any suitable metal material, which has an absorption ratio of about 40% or more and may absorb some of light provided, may be used as the metal dopant contained in the first capping layer CPL1 without limitation.

In the first capping layer CPL1, a volume ratio (vol %) of the first compound to the metal dopant may be about 99:1 to about 95:5. In the first capping layer CPL1, when the volume ratio of the metal dopant is less than about 1 vol %, light absorption of the metal dopant is not sufficient, and thus improvement effect of reflectance for external light is not shown or not sufficient. In embodiments, when the metal dopant is contained in an amount of more than about 5 vol % in the first capping layer CPL1, light absorption ratio of the first capping layer CPL1 increases, and thus luminous efficiency of the light-emitting element may be reduced.

The first capping layer CPL1 may have a thickness (t_{CP1}) of about 100 μm to about 500 μm. The first capping layer CPL1 has a thickness of about 100 μm to about 500 μm, thereby exhibiting a lowering effect of reflectance without reducing luminous efficiency. The first capping layer CPL1 having a thickness of about 100 μm to about 500 μm may be provided in a stacked structure with the second capping layer CPL2, which will be further described herein. Therefore, destructive interference that cancels out the reflection of external light may be induced.

In embodiments, in this specification, each of a specular component included (SCI) reflectance and a specular component excluded (SCE) reflectance was evaluated as the external light reflectance. As used herein, improvements in the external light reflectance correspond to a case where both the SCI reflectance and the SCE reflectance are improved.

The capping layer CPL2 may be directly on the first capping layer CPL1, and may have a second refractive index value smaller than the first refractive index value of the first capping layer CPL1. A difference between the first refractive index and the second refractive index at a wavelength of about 550 nm may be about 0.2 or more.

The capping layer CPL may be between the second electrode EL2 and the encapsulation layer TFE (FIG. 4), may have a stacked structure of the first capping layer CPL1 and the second capping layer CPL2, which have high refractive-index characteristics and have low-refractive-index characteristics, respectively. A difference between the first refractive index of the first capping layer CPL1 and the second refractive index of the second capping layer CPL2 may be about 0.2 or more, and thus the light-emitting element OEL may be made to have characteristics of the reduced reflectance for external light. The stacked structure of first capping layer CPL1 and the second capping layer CPL2, which have the above-described optical properties, is contained, and thus reflected light reflected from the first electrode EL1 or second electrode EL2 toward the outside may be reduced due to destructive interference.

The second capping layer CPL2 may include a second compound having the second refractive index smaller than the first refractive index. The second refractive index may be about 1.4 to about 1.7.

The second compound may be an organic compound and/or an inorganic compound. For example, the second capping layer CPL2, in which the second compound is an inorganic compound, may include: an alkali metal compound such as LiF; an alkaline earth metal compound such as MgF₂; SiON; SiNx; SiOy; and/or the like.

For example, when the second compound is an organic compound, the second capping layer CPL2 may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris (carbazol sol-9-yl)triphenylamine (TCTA), and/or the like, and/or may include an epoxy resin, and/or an acrylate such as methacrylate.

In embodiments, the second capping layer CPL2 may include Compounds CPM2-1, and/or CPM2-2 below. However, an embodiment of the present disclosure is not limited thereto, and organic and/or inorganic material having low-refractive-index characteristics of about 1.7 or less at a wavelength of about 550 nm may be used as the second compound without limitation.

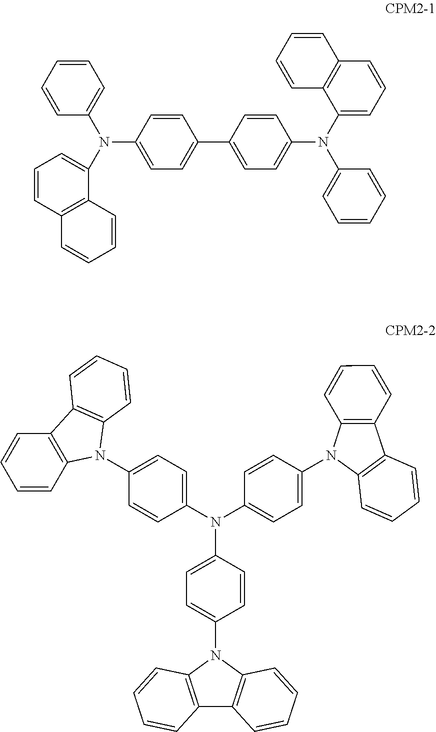 [SMILES: c1ccc(N(c2ccc(-c3ccc(N(c4ccccc4)c4cccc5ccccc45)cc3)cc2)c2cccc3ccccc23)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

The second capping layer CPL2 may have a thickness t_{CP2} of about 100 μm to about 500 μm. Because the second capping layer CPL2 has the thickness of about 100 μm to about 500 μm, a lowering effect of the reflectance may be exhibited without reducing luminous efficiency. The second capping layer CPL2 having the thickness of about 100 μm to about 500 μm may be provided on the first capping layer CPL1 to induce destructive interference that cancels out the emitted light reflected on the bottom of the capping layer.

The light-emitting element according to an embodiment may include: the first capping layer including the first compound, which has high refractive index characteristics, and the metal dopant; and the second capping layer on the first capping layer and including the second compound which has the lower-refractive-index characteristics than the first compound, thereby showing improved optical properties in which reflectance for the external light is reduced. In embodiments, in the light-emitting element according to an embodiment, the stacked structure of the above-described first capping layer and the second capping layer is on the second electrode, and thus excellent luminous efficiency characteristics may be exhibited. The light-emitting element OEL according to an embodiment illustrated in FIG. 5 may be included in the display device DD according to an embodiment described with reference to FIG. 1 to FIG. 4, and the display device DD according to an embodiment may exhibit excellent display quality because the reflectance for the external light is reduced.

The light-emitting element OEL-1 according to an embodiment illustrated in FIG. 6A may include a first electrode EL1, a second electrode EL2 facing the first electrode EL1, and a plurality of emission units EU-1, EU-2, and EU-3 between the first electrode EL1 and the second electrode EL2. In FIG. 6A, a stacked structure in which three of emission units EU-1, EU-2, and EU-3 are stacked on an emission structure ST-1 between the first electrode EL1 and the second electrode EL2, but the structure is illustrated as an example, and the emission structure ST-1 may include two emission units, or four or more emission units.

The light-emitting element OEL-1 according to an embodiment described with reference to FIG. 6A and FIG. 6B may be included in the display layer DP-ED (FIG. 4) of the display device according to an embodiment described with reference to FIG. 1 to FIG. 4. In the light-emitting element OEL-1 according to an embodiment described with reference to FIG. 6A and FIG. 6B, the duplicated content as the content of the light-emitting element OEL described in FIG. 5 will not be described again, and differences will be mainly described.

The light-emitting element OEL-1 according to an embodiment may include a first emission unit EU-1, a second emission unit EU-2, and a third emission unit EU-3, which are sequentially stacked. At least one among the emission units EU-1, EU-2, and EU-3 may emit blue light. The first to third emission units EU-1, EU-2, and EU-3 may all emit blue light, at least one among the first to third emission units EU-1, EU-2, and EU-3 may emit green light and the remaining may emit blue light, or each of the first to third emission units EU-1, EU-2, and EU-3 may emit light in different wavelength regions from each other.

In an embodiment illustrated in FIG. 6A, light generated in the light-emitting element OEL-1 may be emitted in a direction of the top surface of the capping layer CPL, for example, in the third direction DR3.

The light-emitting element OEL-1 according to an embodiment may include charge generation layers CGL-1 and CGL-2 between a plurality of emission units EU-1, EU-2, and EU-3. The light-emitting element OEL-1 according to an embodiment may include the first charge generation layer CGL-1 between the first emission unit EU-1 and the second emission unit EU-2, and the second charge generation layer CGL-2 between the second emission unit EU-2 and the third emission unit EU-3.

When voltage is applied to the light-emitting element OEL-1, the charge generation layers CGL-1 and CGL-2 forms a complex via an oxidation-reduction reaction, and thus charges (electrons and holes) may be generated. In embodiments, the charge generation layer CGL-1 and CGL-2 may provide the generated charges to each of adjacent emission units EU-1, EU-2, and EU-3. The charge generation layers CGL-1 and CGL-2 may make efficiency of current generated in each of the adjacent emission units EU-1, EU-2, and EU-3 increase, and may serve to control balance of the charges between the emission units EU-1, EU-2, and EU-3.

The charge generation layers CGL-1 and CGL-2 may each have a layer structure in which an n-type charge generation layer n-CGL and a p-type charge generation layer p-CGL are bonded to each other.

The n-type charge generation layer n-CGL may provide electrons to the adjacent emission units EU-1, EU-2, and EU-3. The n-type charge generation layer n-CGL may be a layer in which the base material is doped with a n-dopant. The p-type charge generation layer p-CGL may provide holes to the adjacent emission units EU-1, EU-2, and EU-3. The p-type charge generation layer p-CGL may be a layer in which the base material is doped with a p-dopant.

In embodiments, a buffer layer may be further between the n-type charge generation layer n-CGL and the p-type charge generation layer p-CGL.

The charge generation layers CGL-1 and CGL-2 may include a n-type arylamine-based material and/or may include a p-type metal oxide, respectively. For example, each of the charge generation layers CGL-1 and CGL-2 may include a charge generation compound made of an arylamine-based organic compound, a metal, an oxide, carbide, fluoride of a metal, or a mixture thereof.

For example, the arylamine-based organic compound may be α-NPD, 2-TNATA, TDATA, MTDATA, spiro-TAD, and/or spiro-NPB. For example, the metal may be cesium (Cs), molybdenum (Mo), vanadium (V), titanium (Ti), tungsten (W), barium (Ba), and/or lithium (Li). In embodiments, for example, an oxide, carbide, and fluoride of metal may be Re₂O₇, MoO₃, V₂O₅, WO₃, TiO₂, Cs₂CO₃, BaF, LiF, and/or CsF.

In an embodiment, the charge generation layers CGL-1 and CGL-2 may include at least one among CGL1 to CGL3 below. However, an embodiment of the present disclosure is not limited thereto.

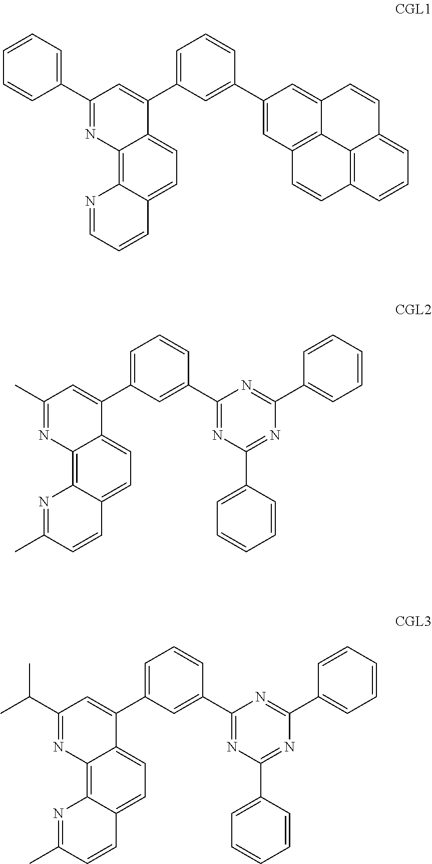 [SMILES: c1ccc(-c2cc(-c3cccc(-c4cc5ccc6cccc7ccc(c4)c5c67)c3)c3ccc4cccnc4c3n2)cc1 ; Cc1ccc2ccc3c(-c4cccc(-c5nc(-c6ccccc6)nc(-c6ccccc6)n5)c4)cc(C)nc3c2n1 ; Cc1ccc2ccc3c(-c4cccc(-c5nc(-c6ccccc6)nc(-c6ccccc6)n5)c4)cc(C(C)C)nc3c2n1]

In FIG. 6A, the stacked structure of three of emission units EU-1, EU-2 and EU-3 and two of the charge generation layers CGL-1 and CGL-2 therebetween are illustrated, but an embodiment of the present disclosure is not limited thereto, and if the number of the stacked emission units increase, the charge generation layer between the emission units may be added corresponding thereto.

A plurality of emission units EU-1, EU-2, and EU-3 may each include the emission layers EML-1, EML-2, and EML-3. The plurality of emission units EU-1, EU-2, and EU-3 may each include hole transport regions HTR-1, HTR-2, and HTR-3, emission layer EML-1, EML-2, and EML-3, electron transport regions ETR-1, ETR-2, ETR-3, respectively. In embodiments, the light-emitting element OEL-1 according to an embodiment may be a light-emitting element having a tandem structure that includes a plurality of emission layers EML-1, EML-2, and EML-3, which are stacked in a thickness direction.

The descriptions of the hole transport region HTR, the emission layer EML, and the electron transport region ETR described with reference to FIG. 5 may be similarly applied to the hole transport regions HTR-1, HTR-2, and HTR-3, the emission layers EML-1, EML-2, and EML-3, and the electron transport regions ETR-1, ETR-2, ETR-3 included in the emission units EU-1, EU-2, and EU-3, respectively.

The plurality of the emission units EU-1, EU-2, and EU-3 may be included in the display layer DP-ED (FIG. 4) of the display device DD (FIG. 4) according to an embodiment. In an embodiment, the plurality of the emission units EU-1, EU-2, and EU-3 may be provided, as a common layer, on the entire first to third pixel regions PXA-R, PXA-G, and PXA-B.

In embodiments, at least one of the plurality of emission units EU-1, EU-2, and EU-3 may be patterned and provided to be distinguished by a pixel defining layer PDL. In embodiments, the emission layers EML-1, EML-2, and EML-3 of the emission units EU-1, EU-2, and EU-3 may be patterned and provided so as to be distinguished by the pixel defining layer PDL.

One of the emission units EU-1, EU-2, and EU-3 included in the light-emitting element OEL-1 according to an embodiment is exemplified in FIG. 6B. One unit emission unit EU may have a stacked structure of the hole transport region HTR, the emission layer EML, and the electron transport region ETR. In the unit emission unit EU, the hole transport region HTR may include at least one among the hole injection layer HIL, and the hole transport layer HTL, and the electron transport region ETR may include at least one among the electron transport layer ETL and the electron injection layer EIL.

In embodiments, in the hole transport region HTR adjacent to the charge generation layers CGL-1 and CGL-2 of the emission units EU-1, EU-2, and EU-3, the hole injection layer HIL may be omitted, and/or the electron injection layer EIL may be omitted. However, an embodiment of the present disclosure is not limited thereto.

In the light-emitting element OEL-1 according to an embodiment illustrated in FIG. 6A, the capping layer CPL may be on the emission structure ST-1 including a plurality of emission units EU-1, EU-2, and EU-3. The capping layer CPL may include a first capping layer CPL1 on the second electrode EL2, and a second capping layer CPL2 on the first capping layer CPL1.

The descriptions for the capping layer described with reference to FIG. 1 to FIG. 5 may be similarly applied to the first capping layer CPL1 and the second capping layer CPL2. In embodiments, the light-emitting element OEL-1 according to an embodiment includes: the first capping layer CPL1 which includes a first compound having high refractive index characteristics and a metal dopant; and the second capping layer CPL2 which is on the first capping layer and includes a second compound having lower refractive index characteristics than the first compound, thereby exhibiting improved optical properties of reduced reflectance for external light. In embodiments, in the light-emitting element according to an embodiment, a stacked structure of the first capping layer and the second capping layer is on the second electrode, thereby exhibiting excellent luminous efficiency characteristics. The light-emitting element OEL-1 according to an embodiment illustrated in FIG. 6A may be included in the display device DD according to an embodiment described with reference to FIG. 1 to FIG. 4, and the display device DD according to an embodiment may have the reduced reflectance for external light to exhibit excellent display quality.

Hereinafter, with reference to Examples and Comparative Examples, evaluation results of characteristics of the display device according to an embodiment will be described. The Examples shown below are only for the understanding of the subject matter of the present disclosure, and the scope of the present disclosure is not limited thereto.

### Manufacture of Display Device

Display devices according to Comparative Examples and Examples each have a structure including a display layer which includes a light-emitting element and an optical control member on the display layer, wherein a low reflection film on the optical control member is included as an anti-reflection layer.

The light-emitting elements used in the display devices according to Comparative Examples and Examples were manufactured based on a structure of the light-emitting element illustrated in FIG. 6A.

A charge generation layer including an n-type charge generation layer and a p-type charge generation layer was provided between the stacked emission structures. The n-type charge generation layer was formed by doping the above-described CGL1 material with Li. On the n-type charge generation layer, the p-type charge generation layer was formed with NPB and F4-TCNQ.

The first electrode was formed to have a structure of ITO/Ag/ITO, and the second electrode was formed of AgMg. In the first emission unit to third emission unit EU-1, EU-2, and EU-3 (FIG. 6A), the hole transport region HTR may include two stacked hole transport layers HTLs. The hole transport layer HTL may include an NPC layer and a TCTA layer, which are sequentially stacked.

In embodiments, the first emission unit EU-1 may further include a hole injection layer HIL disposed on the first electrode EL1, and the hole injection layer HIL in the first emission unit EU-1 may include NPB and F4-TCNQ.

The emission layer in the first emission unit to third emission unit EU-1, EU-2 and EU-3 (FIG. 6A) may each include H1 and D1, which are, respectively, the above-described host material and dopant material.

The electron transport region ETR in the first emission unit to third emission unit EU-1, EU-2 and EU-3 (FIG. 6A) may include two stacked electron transport layers ETLs. The electron transport layer ETL may be formed by including a co-deposited layer by adding LiQ into a T2T layer and TPM-TAZ, which are sequentially stacked.

In embodiments, the third emission unit EU-3 may further include an electron injection layer EIL under the second electrode EL2, and the electron injection layer EIL in the third emission unit EU-3 may include Yb.

In the display devices according to Examples, the first capping layer CPL1 of the light-emitting element was formed by including Compound CPM1 as the first compound and co-depositing Yb and/or Li. The second capping layer CPL2 was formed by including Compound CPM2-2 as the second compound.

The light-emitting element according to Comparative Example 1 was formed such that the first capping layer CPL1 included Compound CPM1 as the first compound, and the second capping layer CPL2 included Compound CPM2-1 as the second compound.

In a case of Comparative Example A1, Yb content was varied to form the first capping layer CPL1 in comparison to Example A1 and, in a case of Comparative Example B1, Li content was varied to form the first capping layer CPL1 in comparison to Example B1 and Example B2.

In cases of Comparative Example C1, C2, and C3, silver (Ag) was used as a metal dopant in the first capping layer CPL1, and Ag content was varied to form the first capping layer CPL1.

In the light-emitting elements according to Comparative Examples and Examples in Table 1, the first capping layer CPL1 was formed to have a thickness of about 500 Å, and the second capping layer CPL2 was formed to have a thickness of about 200 Å.

In Table 2, the light-emitting element according to Comparative Example 2 was formed such that the first capping layer CPL1 included the first compound of CPM1, and the second capping layer CPL2 included the second the second compound of CPM2-1. In the light-emitting elements according to Comparative Example 2 Å, Comparative Example 2B, and Example 2, the first capping layer CPL1 was formed by including Compound CPM1 as the first compound and co-depositing Yb of about 1.0%. The second capping layer CPL2 was formed by including Compound CPM2-2 as the second compound.

In the light-emitting elements according to Comparative Example 2, Comparative Example 2 Å, Comparative Example 2B, and Example 2, the first capping layer CPL1 was formed to have a thickness of about 500 Å. In the light-emitting elements according to Comparative Example 2 and Example 2, the second capping layer CPL2 had a thickness of about 200 Å, and in the light-emitting elements according to Comparative Example 2 Å and Comparative Example 2B, the second capping layer CPL2 had a thickness of about 50 Å, and about 100 Å, respectively.

In the light-emitting elements according to Comparative Examples and Examples listed in Table 1 and Table 2, the % of the metal dopant corresponds to a volume ratio.

The Example Compounds below are compounds used in the manufacture of light-emitting elements according to Comparative Examples and Examples.

### Example Compounds

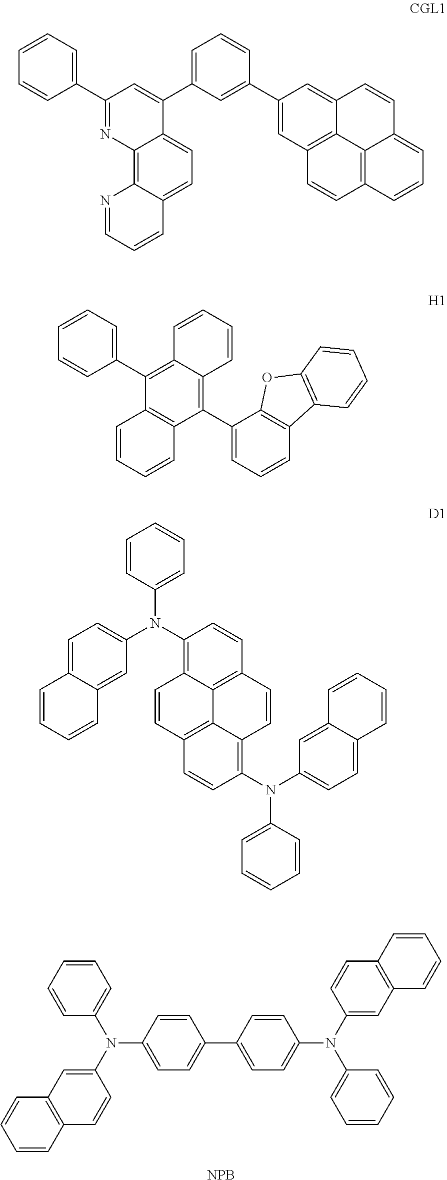 [SMILES: c1ccc(-c2cc(-c3cccc(-c4cc5ccc6cccc7ccc(c4)c5c67)c3)c3ccc4cccnc4c3n2)cc1 ; c1ccc(-c2c3ccccc3c(-c3cccc4c3oc3ccccc34)c3ccccc23)cc1 ; c1ccc(N(c2ccc3ccccc3c2)c2ccc3ccc4c(N(c5ccccc5)c5ccc6ccccc6c5)ccc5ccc2c3c54)cc1 ; c1ccc(N(c2ccc(-c3ccc(N(c4ccccc4)c4ccc5ccccc5c4)cc3)cc2)c2ccc3ccccc3c2)cc1 ; "NPB"]

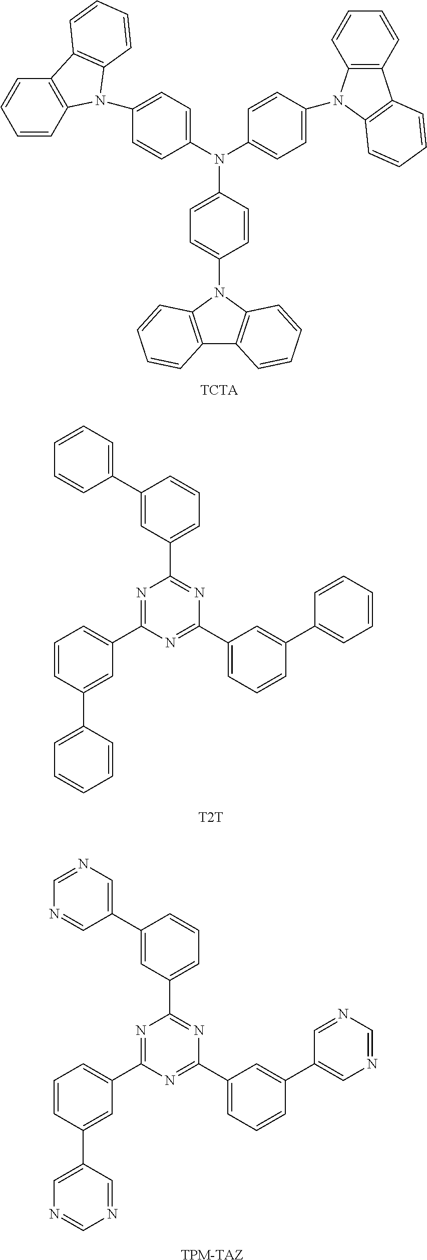 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2cccc(-c3nc(-c4cccc(-c5ccccc5)c4)nc(-c4cccc(-c5ccccc5)c4)n3)c2)cc1 ; "T2T" ; c1cc(-c2cncnc2)cc(-c2nc(-c3cccc(-c4cncnc4)c3)nc(-c3cccc(-c4cncnc4)c3)n2)c1 ; "TPM-TAZ"]

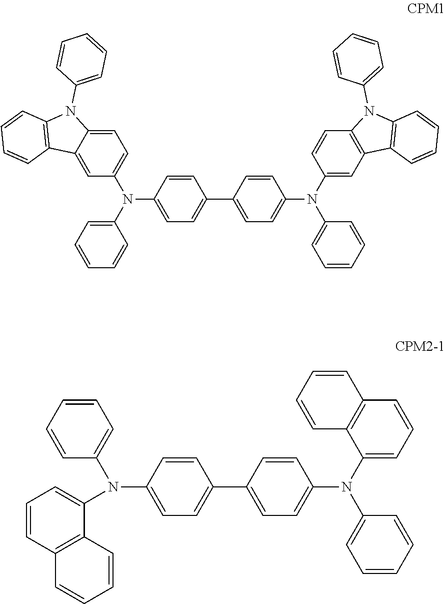 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc(N(c2ccc(-c3ccc(N(c4ccccc4)c4cccc5ccccc45)cc3)cc2)c2cccc3ccccc23)cc1]

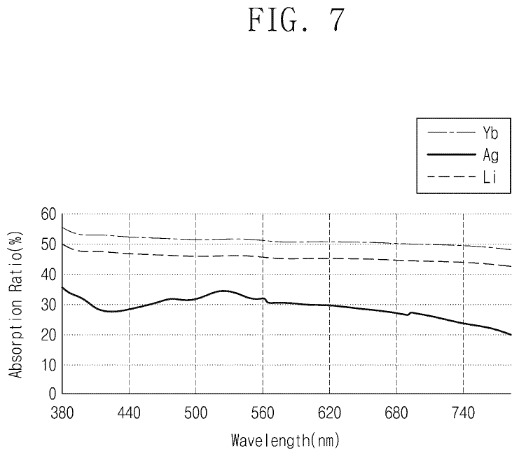

Light absorption properties for the metal dopant materials used in Comparative Examples and Examples are shown in FIG. 7. In FIG. 7, the absorption ratios according to wavelength for Yb, Li, and Ag used in Examples and Comparative Examples were evaluated and the evaluation results were shown in FIG. 7. A thin film using each metal dopant material was formed on a glass substrate and the absorption ratio for provided light so as to transmit through the stacked structure of the glass substrate and the thin film was evaluated and the results was shown by comparison in FIG. 7. The absorption ratio in FIG. 7 was measured using a UV-visible spectrometer, and the thin film formed by using the metal dopant had a thickness of about 300 Å. Referring to the evaluation results of the absorption ratio in FIG. 7, the thin films using Yb and Li, as compared to the thin film using Ag, exhibited high absorption properties in the entire measured wavelength region. The thin films using Yb and Li exhibited the absorption ratio characteristics of about 40% or more throughout the visible wavelength region, and the thin film using Ag exhibited the absorption ratio characteristics of about less than 40% throughout the visible wavelength region.

In the light-emitting elements according to Comparative Examples and Examples, the conditions of the remaining components except for the first capping layer CPL1 were the same.

### Evaluation of Display Device

SCI and SCE reflectance of the light-emitting elements according to Comparative Examples and Examples were evaluated and the results are listed in Table 1 below. SCI and SCE reflectance were measured using CM-26Dg of Konica Minolta Inc.

The reflectance evaluation results in Table 1 are presented in relative terms. The value in the case of Comparative Example 1 was set as 100%, and all other values are expressed as relative percentages based on the value of Comparative Example 1. If the value is larger than 100%, it corresponds to a case where the reflectance is high, and if the value is smaller than 100%, it corresponds to a case where the light-emitting element has decreased reflectance.

TABLE 1

| | | Second | | |
|---|---|---|---|---|
| | First capping layer | capping layer | SCI | SCE |
| Classification | (CPL1) | (CPL2) | (%) | (%) |
| Comparative | First compound | Second | 100 | 100 |
| Example 1 | | compound | | |
| Comparative | First compound, Yb | Second | 100 | 100 |
| Example A1 | 0.5% | compound | | |
| Example A1 | First compound, Yb | Second | 96.6 | 94.3 |
| | 1.0% | compound | | |
| Example A2 | First compound, Yb | Second | 96.6 | 88.5 |
| | 3.0% | compound | | |
| Comparative | First compound, Li | Second | 100 | 100 |
| Example B1 | 0.5% | compound | | |
| Example B1 | First compound, Li | Second | 98.7 | 96.5 |
| | 1.0% | compound | | |
| Example B2 | First compound, Li | Second | 97.2 | 90.5 |
| | 3.0% | compound | | |
| Comparative | First compound, Ag | Second | 100 | 100 |
| Example C1 | 0.5% | compound | | |
| Comparative | First compound, Ag | Second | 102 | 101 |
| Example C2 | 1.0% | compound | | |
| Comparative | First compound, Ag | Second | 104 | 103 |
| Example C3 | 3.0% | compound | | |

Referring to the results in Table 1, it can be seen that when the metal dopant having the absorption ratio of about 40% or greater is included in the first capping layer CPL1 in an amount of about 1.0% or more, the reflectance decreases.

As compared to the light-emitting element according to Comparative Example 1, which includes no metal dopant in the first capping layer CPL1, it can be seen that the light-emitting elements according to Examples A1, and A2, and Examples B1, and B2 have characteristics of the reduced external reflectance. That is, it can be seen that when the metal dopant having the absorption ratio of about 40% or greater is included in addition to the first compound having a high refractive index in the first capping layer CPL1, the reflectance is improved, as compared to the case where the first capping layer CPL1 includes no metal dopant.

When comparing the light-emitting element according to Comparative Example A1 with the light-emitting elements according to Examples A1 and A2, and comparing the light-emitting element according to Comparative Example B1 with the light-emitting elements according to Example B1 and B2, it can be seen that if the first capping layer CPL1 includes the metal dopant in an amount of about 1% or more, a reduced effect on reflectance is shown.

When the light-emitting elements according to Examples were compared to the light-emitting elements according to Comparative Examples C1 to C3, it can be seen that the light-emitting elements according to Examples exhibit reduced reflectance characteristics, but the light-emitting elements according to Comparative Examples C1 to C3, in which the first capping layer CPL1 contains Ag having relatively low absorption ratio characteristics, have reflectance characteristics for external light similar to or greater than that of the light-emitting element according to Comparative Example 1. For example, it can be seen that even when the metal dopant is contained in the first capping layer CPL1 in addition to the first compound having a high refractive index, if the metal dopant, such as Ag having the absorption of less than about 40%, is contained, the external light reflection is not improved.

From the results in Table 1, it can be seen that the display device according to an embodiment includes: the first capping layer CPL1 including the first compound having high refractive index and the metal dopant; and the second capping layer CPL2 on the first capping layer CPL1 and including the second compound with a lower refractive index characteristics, thereby exhibiting improved optical properties of the reduced reflectance for external light. It can be seen, from the results of Examples, that the absorption ratio of the metal dopant is about 40% or greater at about 550 nm, and reduced reflectance is shown when the metal dopant content in the first capping layer CPL1 is about 1 vol % to about 5 vol %.

Reflectance characteristics according to changes in a thickness of the second capping layer CPL2 were evaluated, and the results are listed in Table 2 below. SCI and SCE reflectance for the light-emitting elements according to Comparative Examples and Examples in Table 2 below were measured using CM-26Dg by Konica Minolta Inc.

The reflectance evaluation results in Table 2 are presented in relative terms. The value in a case of Comparative Example 2 was set as 100%, and all other values were expressed as relative percentages based on the value of Comparative Example 2. If the value is smaller than 100%, it corresponds to a case where the reflectance decreased.

TABLE 2

| | First capping | | Second capping | | | |
|---|---|---|---|---|---|---|
| | layer (CPL1) | | layer (CPL2) | | | |
| | | Thick- | | Thick- | | |
| | | ness | | ness | SCI | SCE |
| Classification | Component | (Å) | Component | (Å) | (%) | (%) |
| Comparative | First | 500 | Second | 200 | 100 | 100 |
| Example 2 | Compound | | Compound | | | |
| Comparative | First | 500 | Second | 50 | 98 | 94.7 |
| Example 2A | Compound, | | Compound | | | |
| | Yb 1.0% | | | | | |
| Comparative | First | 500 | Second | 100 | 98 | 94.6 |
| Example 2B | Compound, | | Compound | | | |
| | Yb 1.0% | | | | | |
| Example 2 | First | 500 | Second | 200 | 96.6 | 94.3 |
| | Compound, | | Compound | | | |
| | Yb 1.0% | | | | | |

Referring to the results in Table 2, when comparing the light-emitting element according to Comparative Example 2 with the light-emitting element according to Example 2, it can be seen that improved optical properties of the reduced reflectance for external light may be shown by adding Yb, which is the metal dopant, into the first capping layer.

When comparing the light-emitting elements according to Comparative Example 2 Å, Comparative Example 2B, and Example 2, it can be seen that the light-emitting element according to Example 2, in which the second capping layer CPL2 has a thickness of about 200 Å, shows lower reflectance characteristics than those according to Comparative Example 2 Å and Comparative Example 2B. In comparison to this, it can be seen that the light-emitting element according to Comparative Example 2B, in which the second capping layer CPL2 has a thickness of about 100 Å, has similar reflectance characteristics as that of the light-emitting element according to Comparative Example 2 Å, in which the second capping layer CPL2 has a thickness of about 50 Å. Therefore, it can be seen that when the second capping layer CPL2 has a thickness of about 200 Å or more, an additionally reduced effect on the reflectance may be shown. It is considered that destructive interference between externally reflected light generated on the second capping layer CPL2 and reflected light on the light-emitting elements causes effect of reduced reflectance. Therefore, it can be seen from, the results in Table 1 and Table 2, that the display device according to an embodiment including: the first capping layer CPL1 which includes the first compound having high refractive index characteristics, and the metal dopant; and the second capping layer CPL2 on the first capping layer CPL1 and including the second compound having lower refractive index characteristics than the first compound may exhibit improved optical properties of reduced reflectance for external light. From the results of Examples, it can be confirmed that when the absorption ratio of the metal dopant is about 40% or greater at a wavelength of about 550 nm and the metal dopant content in the first capping layer CPL1 is about 1 vol % to about 5 vol %, the display device has reduced reflectance characteristics. In embodiments, it can be seen that when the second capping layer has a thickness of about 200 Å or greater, the reduced effect on reflectance is more significant.

The light-emitting element according to an embodiment includes: the first capping layer stacked on the emission structure and including the materials having high refractive index and the metal dopant; and the second capping layer on the first capping layer and having lower refractive index characteristics than the first capping layer, and thus may exhibit characteristics of reduced reflectance for external light.

The display device according to an embodiment includes the light-emitting element including: the first capping layer including the materials having high refractive index and the metal dopant; and the second capping layer on the first capping layer and having lower refractive index characteristics than the first capping layer, and thus external light reflected by the electrodes of the light-emitting element is minimized or reduced, thereby exhibiting excellent display quality.

Hitherto, although the subject matter of the present disclosure has been described with reference to example embodiments of the present disclosure, it will be understood that the present disclosure should not be limited to these example embodiments, but various suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light-emitting element comprising:
a first electrode;
a second electrode facing the first electrode;
an emission structure between the first electrode and the second electrode;
a first capping layer on the second electrode and comprising a first compound having a first refractive index of about 1.9 or greater at a wavelength of about 550 nm and a metal dopant having an absorption ratio of about 40% or more at the wavelength of about 550 nm; and
a second capping layer on the first capping layer and comprising a second compound having a second refractive index smaller than the first refractive index.

2. The light-emitting element of claim 1, wherein a difference between the first refractive index and the second refractive index is about 0.2 or greater.

3. The light-emitting element of claim 2, wherein the second refractive index is about 1.4 to about 1.7.

4. The light-emitting element of claim 1, wherein the metal dopant is an alkali metal, an alkaline earth metal, a lanthanide metal, and/or a transition metal.

5. The light-emitting element of claim 1, wherein the metal dopant is lithium (Li) and/or ytterbium (Yb).

6. The light-emitting element of claim 1, wherein a volume ratio of the first compound to the metal dopant in the first capping layer is about 99:1 to about 95:5.

7. The light-emitting element of claim 1, wherein thicknesses of the first capping layer and the second capping layer are each independently about 100 Å to about 500 Å.

8. The light-emitting element of claim 1, wherein the emission structure comprises an emission layer on the first electrode, a hole transport region between the first electrode and the emission layer, and an electron transport region between the emission layer and the second electrode.

9. The light-emitting element of claim 1, wherein the emission structure comprises:
a plurality of emission units, which are sequentially stacked and each comprises a hole transport region, an emission layer and an electron transport region, and
a charge generation layer, which are between each of the plurality of emission units between the first electrode and the second electrode.

10. The light-emitting element of claim 1, wherein the emission structure emits blue light.

11. The light-emitting element of claim 1, wherein the first compound is an organic material, and the second compound is an organic material or inorganic material.

12. A display device comprising:
a light-emitting element that emits a source light; and
an optical control layer on the light-emitting element and configured to transmit the source light or convert a wavelength of the source light,
wherein the light-emitting element comprises:
a first electrode;
a second electrode facing the first electrode;
an emission structure between the first electrode and the second electrode;
a first capping layer on the second electrode and comprising a first compound having a first refractive index of about 1.9 or greater at a wavelength of 550 nm, and a metal dopant having an absorption ratio of about 40% or more at the wavelength of 550 nm; and
a second capping layer on the first capping layer and comprising a second compound having a second refractive index smaller than the first refractive index.

13. The display device of claim 12, wherein a difference between the first refractive index and the second refractive index is about 0.2 or greater, and the second refractive index is about 1.4 to about 1.7.

14. The display device of claim 12, wherein the metal dopant is an alkali metal, an alkaline earth metal, a lanthanide metal, and/or a transition metal.

15. The display device of claim 12, wherein a volume ratio of the first compound to the metal dopant in the first capping layer is about 99:1 to about 95:5.

16. The display device of claim 12, wherein thicknesses of the first capping layer and the second capping layer are each independently about 100 Å to about 500 Å.

17. The display device of claim 12 comprising:
a first pixel region that emits red light;
a second pixel region that emits green light; and
a third pixel region that emits blue light, wherein the first pixel region, the second pixel region, and the third pixel region do not overlap on a plane,
wherein the optical control layer comprises:
a first optical control member provided corresponding to the first pixel region and comprising a first quantum dot which converts a wavelength of the source light;
a second optical control member provided corresponding to the second pixel region and comprising a second quantum dot which converts a wavelength of the source light; and
a third optical control member provided corresponding to the third pixel region.

18. A display device comprising:
a circuit layer;
a light-emitting element on the circuit layer; and
an encapsulation layer on the light-emitting element,
wherein the light-emitting element comprises:
a first electrode;
a second electrode facing the first electrode;
an emission structure between the first electrode and the second electrode;
a first capping layer on the second electrode and comprising a first compound having a first refractive index of about 1.9 or greater at a wavelength of 550 nm and a metal dopant having an absorption ratio of about 40% or more at the wavelength of 550 nm, and
a second capping layer on the first capping layer and comprising a second compound having a second refractive index smaller than the first refractive index.

19. The display device of claim 18, wherein the encapsulation layer is directly on the second capping layer.

20. The display device of claim 18, wherein a volume ratio of the first compound to the metal dopant in the first capping layer is about 99:1 to about 95:5.
